(19) United States
(12) Patent Application Publication
(10) Pub. No.: US 2004/0084774 A1
(43) Pub. Date: May 6, 2004

(54) Gas layer formation materials

(76) Inventors: Bo Li, San Jose, CA (US); De-Ling Zhou, Sunnyvale, CA (US); Ananth Naman, San Jose, CA (US); Paul G. Apen, San Francisco, CA (US)

Correspondence Address: Honeywell International Inc., 15801 Woods Edge Road, Colonial Heights, VA, 23834, US

(21) Appl. No.: 10/286,236

(22) Filed: Nov. 2, 2002

(51) Int. Cl. H01L 21/4763; H01L 23/48; H01L 29/40; H01L 21/31

(52) U.S. Cl. 257/758; 438/622; 438/623; 257/759

(57) ABSTRACT

The present invention provides gas layer formation material selected from the group consisting of acenaphthylene homopolymers; acenaphthylene copolymers; poly(arylene ether); polyamide; B-staged multifunctional acrylate/methacrylate; crosslinked styrene divinyl benzene polymers; and copolymers of styrene and divinyl benzene with maleimide or bis-maleimides. The formed gas layers are used in microchips and multichip modules.

### FIELD OF THE INVENTION

The present invention relates to semiconductor devices, and in particular, to semiconductor devices having a gas layer therein.

### BACKGROUND OF THE INVENTION

In an effort to increase the performance and speed of semiconductor devices, semiconductor device manufacturers have sought to reduce the linewidth and spacing of interconnects while minimizing the transmission losses and reducing the capacitative coupling of the interconnects. One way to diminish power consumption and reduce capacitance is by decreasing the dielectric constant (also referred to as “k”) of the insulating material, or dielectric, that separates the interconnects. Insulator materials having low dielectric constants are especially desirable, because they typically allow faster signal propagation, reduce capacitance and cross talk between conductor lines, and lower voltages required to drive integrated circuits.

Since air has a dielectric constant of 1.0, a major goal is to reduce the dielectric constant of insulator materials down to a theoretical limit of 1.0, and several methods are known in the art for reducing the dielectric constant of insulating materials. These techniques include adding elements such as fluorine to the composition to reduce the dielectric constant of the bulk material. Other methods to reduce k include use of alternative dielectric material matrices. Another approach is to introduce pores into the matrix.

Therefore, as interconnect linewidths decrease, concomitant decreases in the dielectric constant of the insulating material are required to achieve the improved performance and speed desired of future semiconductor devices. For example, devices having minimum feature sizes of 0.13 or 0.10 micron and below seek an insulating material having a dielectric constant (k)<3.

Currently silicon dioxide (SiO₂) and modified versions of SiO₂, such as fluorinated silicon dioxide or fluorinated silicon glass (hereinafter FSG) are used. These oxides, which have a dielectric constant ranging from about 3.5-4.0, are commonly used as the dielectric in semiconductor devices. While SiO₂ and FSG have the mechanical and thermal stability needed to withstand the thermal cycling and processing steps of semiconductor device manufacturing, materials having a lower dielectric constant are desired in the industry.

Methods used to deposit dielectric materials may be divided into two categories: spin-on deposition (hereinafter SOD) and chemical vapor deposition (hereinafter CVD). Several efforts to develop lower dielectric constant materials include altering the chemical composition (organic, inorganic, blend of organic/inorganic) or changing the dielectric matrix (porous, non-porous). Table 1 summarizes the development of several materials having dielectric constants ranging from 2.0 to 3.9. (PE=plasma enhanced; HDP=high-density plasma) However, the dielectric materials and matrices disclosed in the publications shown in Table 1 fail to exhibit many of the combined physical and chemical properties desirable and even necessary for effective dielectric materials, such as higher mechanical stability, high thermal stability, high glass transition temperature, high modulus or hardness, while at the same time still being able to be solvated, spun, or deposited on to a substrate, wafer, or other surface. Therefore, it may be useful to investigate other compounds and materials that may be used as dielectric materials and layers, even though these compounds or materials may not be currently contemplated as dielectric materials in their present form.

TABLE 1

| | DEPOSITION | DIELECTRIC | |
|---|---|---|---|
| MATERIAL | METHOD | CONSTANT (k) | REFERENCE |
| Fluorinated silicon oxide | PE-CVD; | 3.3-3.5 | U.S. Pat. No. 6,278,174 |
| (SiOF) | HDP-CVD | | |
| Hydrogen | SOD | 2.0-2.5 | U.S. Pat. No.s 4,756,977; 5,370,903; and |
| Silsesquioxane (HSQ) | | | 5,486,564; International Patent Publication |
| | | | WO 00/40637; E.S. Moyer et al., |
| | | | “Ultra Low k Silsesquioxane Based Resins”, |
| | | | Concepts and Needs for Low Dielectric |
| | | | Constant <0.15 μm Interconnect Materials: |
| | | | Now and the Next Millennium, Sponsored by |
| | | | the American Chemical Society, pages 128- |
| | | | 146 (November 14-17, 1999) |
| Methyl Silsesquioxane | SOD | 2.4-2.7 | U.S. Pat. No. 6,143,855 |
| (MSQ) | | | |
| Polyorganosilicon | SOD | 2.5-2.6 | U.S. Pat. No. 6,225,238 |
| Fluorinated Amorphous | HDP-CVD | 2.3 | U.S. Pat. No. 5,900,290 |
| Carbon (a-C:F) | | | |
| Benzocyclobutene (BCB) | SOD | 2.4-2.7 | U.S. Pat. No. 5,225,586 |
| Polyarylene Ether (PAE) | SOD | 2.4 | U.S. Pat. Nos. 5,986,045; 5,874,516; and |
| | | | 5,658,994 |
| Parylene (N and F) | CVD | 2.4 | U.S. Pat. No. 5,268,202 |
| Polyphenylenes | SOD | 2.6 | U.S. Pat. Nos. 5,965,679 and 6,288,188B1; |
| | | | and Waeterloos et al., “Integration Feasibility |
| | | | of Porous SiLK Semiconductor Dielectric”, |
| | | | Proc. Of the 2001 International Interconnect |
| | | | Tech. Conf., pp. 253-254 (2001). |
| Thermosettable | SOD | 2.3 | International Patent Publication WO |
| benzocyclobutenes, | | | 00/31183 |
| polyarylenes, | | | |
| thermosettable | | | |
| perfluoroethylene | | | |
| monomer | | | |
| Poly(phenylquinoxaline), | SOD | 2.3-3.0 | U.S. Pat. Nos. 5,776,990; 5,895,263; |
| organic polysilica | | | 6,107,357; and 6,342,454; and U.S. patent |
| | | | Publication 2001/0040294 |
| Organic polysilica | SOD | Not reported | U.S. Pat. No. 6,271,273 |
| Organic and inorganic | SOD | 2.0-2.5 | Honeywell U.S. Pat. No. 6,1 56,812 |
| Materials | | | |
| Organic and inorganic | SOD | 2.0-2.3 | Honeywell U.S. Pat. No. 6,171,687 |
| Materials | | | |
| Organic materials | SOD | Not reported | Hone well U.S. Pat. No. 6,172,128 |
| Organic | SOD | 2.12 | Honeywell U.S. Pat. No. 6,214,746 |
| Organic and inorganic | SOD | Not reported | Honeywell U.S. Pat. No. 6,313,185 |
| materials | | | |
| Organosilsesquioxane | CVD, SOD | <3.9 | Honeywell WO 01/29052 |
| Fluorosilsesquioxane | CVD, SOD | <3.9 | Honeywell U.S. Pat. No. 6,440,550 |
| Organic and inorganic | SOD | ≦2.5 | Honeywell U.S. Pat. No. 6,380,270 |
| materials | | | |
| Organic materials | — | <3.0 | Honeywell U.S. Pat. No. 6,380,347 |
| Cage based structure | SOD | <2.7 | Honeywell Serial 10/158513 |
| | | | filed May 30, 2002 |
| Cage based structure | SOD | <3.0 | Honeywell Serial 10/158548 |
| | | | filed May 30, 2002 |

Another approach to decrease the dielectric constant of a semiconductor device is the inclusion of an air gap. One method for air gap formation is etching the oxide between selected copper lines as taught by V. Arnal, “Integration of a 3 Level Cu—SiO₂ Air Gap Interconnect for Sub 0.1 Micron CMOS Technologies”, 2001 Proceedings of International Interconnect Technology Conference (Jun. 4-6, 2001). Because SiO₂ has a dielectric constant of around 4.0, any unetched oxide is contributing to an undesirable k_{effective} defined as the dielectric constant of an inter-level dielectric structure comprising the bulk dielectric, cap, etch stop, and hardmask. See also U.S. Pat. No, 5,117,276 to Michael E. Thomas et al. See also U.S. Pat. Nos. 6,268,262; 6,268,277 and 6,277,705.

Another way to generate air gaps is to use non-conformal silane deposition techniques resulting in “breadloafing” at upper corners of metal lines as taught by B.P. Shieh et al., “Electromigration Reliability of Low Capacitance Air-Gap Interconnect Structures”, 2002 Proceedings of International Interconnect Technology Conference (Jun. 3-5, 2002). The preceding approach yields undesirable irregular shapes and an air gap that is either higher than the metal wire resulting in mechanical disadvantage or smaller than desired resulting in a higher k_{effective}. See also U.S. Pat. Nos. 6,281,585 and 6,376,330.

Hollie A. Reed et al., “Porous Dielectrics and Air-Gaps Created by Sacrificial Placeholders”, International SEMATECH Ultra Low k Workshop (Jun. 6-7, 2002) teaches that polycarbonates and polynorbornene homopolymer may be used to fabricate air gaps. U.S. Patent Application Publication 2002/0122648 teaches air gap formation materials comprising polynorbornene; polycarbonates; polyethers; and polyesters. U.S. Patent Application Publication 2002/0136481 also teaches that a useful air gap formation material is polyformaldehyde. See also U.S. Pat. No. 6,316,347. U.S. Pat. No. 6,380,106 teaches the use of a vaporizable filler material consisting of polyethylene glycol, polypropylene glycol, polybutadiene, fluorinated amorphous carbon, and polycaprolactone diol. International Publication WO 02/19416 teaches air gap polymers such as polymethyl methacrylate, polystyrene, and polyvinyl alcohol. U.S. Pat. No. 6,346,484 teaches air gap formation materials such as poly(methylacrylate), parylene, and norborene-based materials.

In our copending patent application Ser. No. 10/158513 filed May 30, 2002, we disclosed and claimed porogens comprising unfunctionalized polyacenaphthylene homopolymer; functionalized polyacenaphthylene homopolymer; polyacenaphthylene copolymers; poly(2-vinylnaphthalene); and poly(vinyl anthracene); and blends with each other.

Semiconductors manufacturers are demanding an improved gas layer formation material and in particular, a material that after being held at 300° C. for one hour, has less than two percent weight loss to ensure dimensional and chemical stability during processing steps including but not limited to etching and cleaning before thermal decomposition of the material. Unfortunately, polynorbornene homopolymer and copolymer do not meet this stringent industry requirement as seen in FIGS. 1 and 2. Since the Hollie A. Reed et al. article does not mention this industry requirement, the Hollie A. Reed et al. article would not lead one skilled in the art to the present invention meeting this industry need. In addition, polyethylene glycol, polypropylene glycol, and polybutadiene do not meet this industry requirement. In addition, Hollie A. Reed et al. teaches a polyimide capping layer that due to its nitrogen content, is undesirable in integration schemes.

In addition, a material that has a glass transition temperature (Tg) of at least about 200° C. is required to withstand the demanding integration processing requirements. Unfortunately, U.S. Pat. No. 6,380,106's polyethylene glycol, polypropylene glycol, polybutadiene, fluorinated amorphous carbon, and polycaprolactone diol have a Tg less than 200° C.

### SUMMARY OF THE INVENTION

The present invention responds to this need in the art by providing materials and processes that after holding at 300° C. for one hour, have less than two percent weight loss and also result in an advantageously lower k_{effective} and more uniform gas layer formation. The present materials also have good mechanical properties, adhesion, chemical and thermal stability, a range of achievable film thicknesses, low outgassing, low k_{effective} after thermal decomposition, and decomposition profile making them attractive candidates for integration under demanding semiconductor manufacturing conditions.

The present invention provides gas layer formation materials selected from the group consisting of acenaphthylene homopolymers; acenaphthylene copolymers; norbornene and acenaphthylene copolymer; polynorbornene derivatives; blend of polynorbornene and polyacenaphthylene; poly(arylene ether); polyamide; B-staged multifunctional acrylate/methacrylate; crosslinked styrene divinyl benzene polymers; and copolymers of styrene and divinyl benzene with maleimide or bis-maleimides. Preferably, the materials have less than two percent weight loss after holding at 300° C for one hour.

The present invention also provides a method of forming a gas layer comprising the step of: using a material selected from the group consisting of acenaphthylene homopolymers; acenaphthylene copolymers; norbornene and acenaphthylene copolymer; polynorbornene derivatives; blend of polynorbornene and polyacenaphthylene; poly(arylene ether); polyamide; B-staged multifunctional acrylate/methacrylate; crosslinked styrene divinyl benzene polymers; and copolymers of styrene and divinyl benzene with maleimide or bis-maleimides. Preferably, the material has less than two percent weight loss after holding at 300° C. for one hour.

The present invention provides a process comprising the steps of:

(a) in an inter-level dielectric layer, incorporating a polymer having: (I) a glass transition temperature of greater than about 200° C., (ii) less than two percent weight loss after holding at 300° C. for one hour, and (iii) a decomposition temperature of greater than about 350° C.;

(b) heating the polymer to a temperature of greater than about 350° C.; and

(c) removing the heated polymer from the inter-level dielectric layer.

The present invention also provides a microchip comprising a gas layer wherein the gas layer is formed by:

(a) forming a layer of polymer having: (i) a glass transition temperature of greater than about 200° C., (ii) less than two percent weight loss after holding at 300° C. for one hour, and (iii) a decomposition temperature of greater than about 350° C.;

(b) decomposing the polymeric layer; and

(c ) volatilizing the decomposed polymeric layer wherein the gas layer forms.

### BRIEF DESCRIPTION OF THE DRAWINGS

FIG. 1 is the ITGA plot for polynorbornene copolymer 1 (PNB 1) in the Comparative below.

FIG. 2 is the ITGA plot for polynorbornene copolymer 2 (PNB 2) in the Comparative below.

FIG. 3 is the ITGA plot for acenaphthylene homopolymer for Inventive Example 15 below.

FIG. 4 illustrates an integration scheme using the present invention.

FIG. 5 illustrates another integration scheme using the present invention.

### DETAILED DESCRIPTION OF THE INVENTION

The term “gas layer” as used herein includes film or coating having voids or cells in an inter-level dielectric layer in a microelectronic device and any other term meaning space occupied by gas in an inter-level dielectric layer in a microelectronic device. Appropriate gases include relatively pure gases and mixtures thereof. Air, which is predominantly a mixture of N₂ and O₂, is commonly distributed in the pores but pure gases such as nitrogen, helium, argon, CO₂, or CO are also contemplated. “Gas layer formation materials” as used herein are capable of being formed into a layer, film, or coating; processed; and removed.

Polymer:

The present polymer may be degraded thermally; by exposure to radiation, mechanical energy, or particle radiation; or by solvent extraction or chemical etching. A thermally degradable polymer is preferred. The term “thermally degradable polymer” as used herein means a decomposable polymer that is thermally decomposable, degradable, depolymerizable, or otherwise capable of breaking down and includes solid, liquid, or gaseous material. The decomposed polymer is removable from or can volatilize or diffuse through a partially or fully cross-linked matrix to create a gas layer in the interlevel dielectric layer in the microelectronic device and thus, lowers the interlevel dielectric layer's dielectric constant. Supercritical materials such as CO₂ may be used to remove the thermally degradable polymer and decomposed thermally degradable polymer fragments. More preferably, the thermally degradable polymer has a glass transition temperature (Tg) of greater than about 300° C. Preferably, the present thermally degradable polymers have a degradation or decomposition temperature of about 350° C. or greater. Preferably, the degraded or decomposed thermally degradable polymers volatilize at a temperature of about 280° C. or greater.

Useful thermally degradable polymers preferably include acenaphthylene homopolymers; acenaphthylene copolymers; norbornene and acenaphthylene copolymer; polynorbornene derivatives; blend of polynorbornene and polyacenaphthylene; poly(arylene ether); polyamide; B-staged multifunctional acrylate/methacrylate; crosslinked styrene divinyl benzene polymers; and copolymers of styrene and divinyl benzene with maleimide or bis-maleimides.

Useful polyacenaphthylene homopolymers may have weight average molecular weights ranging from preferably about 300 to about 100,000 and more preferably about 15,000 to about 70,000 and may be polymerized from acenaphthylene using different initiators such as 2,2′-azobisisobutyronitrile (AIBN); di-tert-butyl azodicarboxylate; di-isopropyl azodicarboxylate; di-ethyl azodicarboxylate; di-benzyl azodicarboxylate; di-phenyl azodicarboxylate; 1,1′-azobis(cyclohexanecarbonitrile); benzoyl peroxide (BPO); t-butyl peroxide; and boron trifluoride diethyl etherate. The functionalized polyacenaphthylene homopolymer may have end groups such as triple bonds or double bonds to the chain end by cationic polymerization quenched with a double or triple bond alcohol such as allyl alcohol; propargyl alcohol; butynol; butenol; or hydroxyethylmethacrylate.

European Patent Publication 315453 teaches that silica and certain metal oxides may react with carbon to form volatile sub oxides and gaseous carbon oxide to form pores and teaches that sources of carbon include any suitable organic polymer including polyacenaphthylene. However, the reference does not teach or suggest that polyacenaphthylene is a gas layer formation material.

Useful polyacenaphthylene copolymers may be linear polymers, star polymers, or hyperbranched. The comonomer may have a bulky side group that will result in copolymer conformation that is similar to that of polyacenaphthylene homopolymer or a nonbulky side group that will result in copolymer conformation that is dissimilar to that of polyacenaphthylene homopolymer. Comonomers having a bulky side group include vinyl pivalate; tert-butyl acrylate; styrene; α-methylstyrene; tert-butylstyrene; 2-vinylnaphthalene; 5-vinyl-2-norbornene; vinyl cyclohexane; vinyl cyclopentane; 9-vinylanthracene; 4-vinylbiphenyl; tetraphenylbutadiene; stilbene; tert-butylstilbene; and indene; and preferably, vinyl pivalate. Hydridopolycarbosilane may be used as an additional co-monomer or copolymer component with acenaphthylene and at least one of the preceding comonomers. An example of a useful hydridopolycarbosilane has 10% or 75% allyl groups. Comonomers having a nonbulky side group include vinyl acetate; methyl acrylate; methyl methacrylate; and vinyl ether and preferably, vinyl acetate.

Preferably, the amount of comonomer ranges from about 5 to about 50 mole percent of the copolymer. These copolymers may be made by free radical polymerization using initiator. Useful initiators include preferably 2,2′-azobisisobutyronitrile (AIBN); di-tert-butyl azodicarboxylate; di-isopropyl azodicarboxylate; di-ethyl azodicarboxylate; di-benzyl azodicarboxylate; di-phenyl azodicarboxylate; 1,1′-azobis(cyclohexanecarbonitrile); benzoyl peroxide (BPO); and t-butyl peroxide and more preferably, AIBN. Copolymers may also be made by cationic polymerization using initiator such as boron trifluoride diethyl etherate. Preferably, the copolymers have a molecular weight from about 15,000 to about 70,000.

Thermal properties of copolymers of acenaphthylene and comonomers are set forth in the following Table 2. In Table 2, BA stands for butyl acrylate; VP stands for vinyl pivalate; VA stands for vinyl acetate; AIBN stands for 2,2′-azobisisobutyronitrile; BF₃ stands for boron trifluoride diethyl etherate; DBADC stands for di-tert-butyl azodicarboxylate; W1 stands for weight loss percentage from room temperature to 250° C.; W2 stands for weight loss percentage at 250° C. for 10 minutes; W3 stands for weight loss percentage from 250° C. to 400° C.; W4 stands for weight loss percentage at 400° C. for one hour; and W5 stands for total weight loss.

TABLE 2

| | | | Comonomer | | | Temp. | | | | | | | | |
|---|---|---|---|---|---|---|---|---|---|---|---|---|---|---|
| Comonomer | Copolymer | Initiator | % | Initiator % | Solvent | (° C.) | Time (hr) | W1 | W2 | W3 | W4 | W5 | Mn | Mw |
| BA | 1 | AIBN | 11 | 1 | Xylene | 70 | 24 | 14.63 | 1.02 | 33.14 | 30.44 | 79.23 | 4797 | 10552 |
| BA | 2 | AIEN | 20 | 1 | Xylene | 70 | 24 | 1.47 | 0.98 | 37.92 | 35.55 | 75.92 | 4343 | 8103 |
| BA | 3 | AIBN | 30 | 1 | Xylene | 70 | 24 | 13.41 | 1.6 | 36.48 | 27.55 | 79.04 | 4638 | 7826 |
| BA | 4 | AIBN | 50 | 1 | Xylene | 70 | 24 | 10.01 | 2.96 | 46.92 | 26.51 | 86.40 | 3504 | 5489 |
| BA | 5 | BF3 | 10 | 3 | Xylene | 5 | 2 | 11.93 | 0.58 | 40.06 | 29.33 | 81.90 | 1502 | 2421 |
| VP | 6 | AIBN | 10 | 1 | Xylene | 70 | 24 | 16.22 | 0.41 | 37.8 | 34.72 | 89.15 | 5442 | 10007 |
| VP | 7 | AIBN | 16 | 1 | THF | 60 | 12 | 5.32 | 0.66 | 46.55 | 29.59 | 82.12 | 1598 | 2422 |
| VP | 8 | AIBN | 25 | 1 | Xylene | 70 | 24 | 4.15 | 0.37 | 24.98 | 47.4 | 76.90 | 2657 | 8621 |
| VP | 9 | AIBN | 30 | 1 | Xylene | 70 | 24 | 14.7 | 0.69 | 33.27 | 39.54 | 88.20 | 5342 | 9303 |
| VP | 10 | AIBN | 40 | 1 | Xylene | 70 | 24 | 6.34 | 0.26 | 33.69 | 39.38 | 76.67 | 4612 | 7782 |
| VP | 11 | AIBN | 50 | 1 | Xylene | 70 | 24 | 14.12 | 0.32 | 29.01 | 37.86 | 81.31 | 4037 | 6405 |
| VP | 12 | BF3 | 10 | 1 | Xylene | 5 | 2 | 0.84 | 0 | 55.51 | 39.38 | 95.73 | 2078 | 3229 |
| VP | 13 | BF3 | 10 | 3 | Xylene | 5 | 2 | 2.26 | 0.06 | 47.44 | 28.93 | 78.69 | 1786 | 2821 |
| VP | 14 | BF3 | 25 | 1 | Xylene | 5 | 2 | 0.17 | 0 | 36.99 | 41,17 | 78.33 | 2381 | 3549 |
| VP | 15 | BF3 | 25 | 3 | Xylene | 5 | 2 | 1.33 | 0.03 | 35.28 | 41.08 | 77,72 | 2108 | 3267 |
| VP | 16 | BF3 | 40 | 1 | Xylene | 5 | 2 | 0.23 | 0.04 | 36.46 | 42.17 | 78.90 | 2659 | 3692 |
| VP | 17 | BF3 | 40 | 3 | Xylene | 5 | 2 | 0.28 | 0.01 | 40.23 | 38.98 | 79.50 | 2270 | 3376 |
| VA | 18 | AIBN | 20 | 2 | Xylene | 70 | 24 | 16.93 | 1.346 | 38.42 | 21.43 | 78.13 | 3404 | 7193 |
| VA | 19 | AIBN | 40 | 2 | Xyiene | 70 | 24 | 15.45 | 1.631 | 31.28 | 31.64 | 80.00 | 3109 | 6141 |

Preferred polyvinyinorbornene are of the following formula

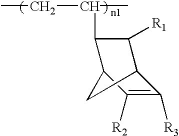

where n₁ is from 50 to 1,000 and R₁, R₂, and R₃ are hydrogen, alkyl, alkyl, or aryl.

Preferred polynorbornene derivatives include polynorbornene-co-acenaphthylenes of the following formula

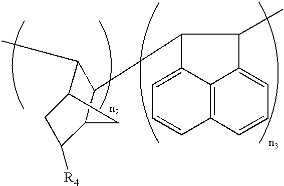

where the copolymer may be randon or block; R₄ is selected from phenyl, biphenyl, n-butyl, n-hexyl, hydrogen, —Si(OCH₃)₃, —Si(OC₂H₅)₃, —Si(OAc)₃, and —SiCl₃; n₂≠O, n₃≠O, and n₂+n₃=100%;

polynorbornene-co-indenes of the following formula

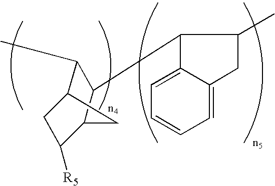

Where the copolymer may be random or block; R₅ is selected from phenyl, biphenyl, n-butyl, n-hexyl, hydrogen, —Si(OCH₃)₃, —Si(OC₂H₅)₃, —Si(OAc)₃, and —SiCl₃; n₄≠O; n₅≠O; and n₄+n₅=100%;

copolynorbornene-co-acenaphthylenes of the following formula

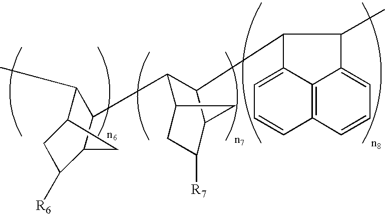

Where the tripolymer may be random or block; R₆ and R₇ are independently selected from phenyl, biphenyl, n-butyl, n-hexyl, hydrogen, —Si(OCH₃)₃, —Si(OC₂H₅)₃, —Si(OAc)₃, and —SiCl₃; n₆≠O; n₇≠O; n₈≠O; and n₆+n₇+n₈=100%;

Copolynorbornene-co-indene of the following formula

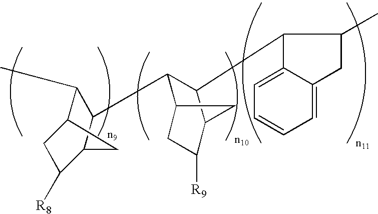

Where the tripolymer may be random or block; R₈ and R₉ are independently selected from phenyl, biphenyl, n-butyl, n-hexyl, hydrogen, —Si(OCH₃)₃, —Si(OC₂H₅)₃, —Si(OAc)₃, and —SiCl₃; n₉≠O; n₁₀≠O; n₁₁≠O; and n₉+n₁₀+n₁₁=100%;

Preferred crosslinked systems include vinyl systems of the following formula

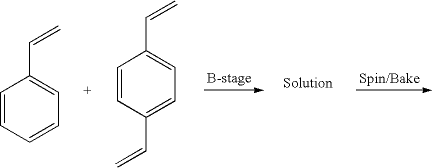

Other vinyl monomers include maleimides and bis-maleimides as co-monomers and crosslinking groups with styrene and/or divinyl benzene. Useful chemistries are taught by Mark A. Hoisington, Joseph R. Duke, and Paul G. Apen, “High Temperature, Polymeric, Structural Foams from High Internal Phase Emulsion Polymerizations” (1996) and P. Hodge et al., “Preparation of Crosslinked Polymers using Acenaphthylene and the Chemical Modification of these Polymers”, Polymers 26(11) (1985) incorporated herein in their entireties.

Other preferred crosslinked systems include acrylate and/or methacrylate systems as follows

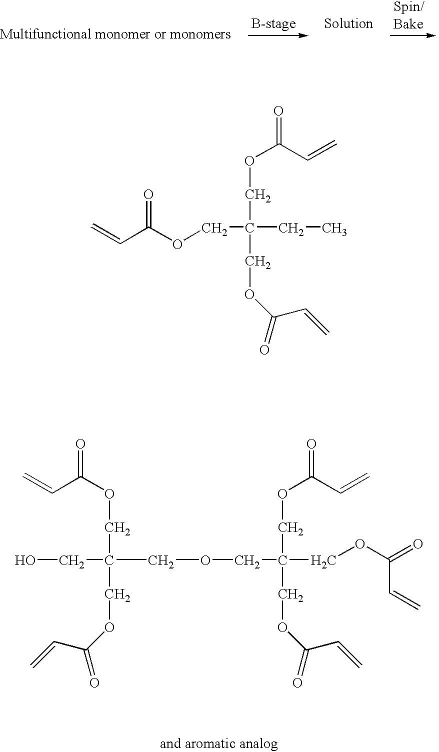

Other useful thermally degradable polymers include cellulose and polyhydrocarbon.

Poly(arylene ether) compositions such as disclosed in commonly assigned U.S. Pat. Nos. 5,986,045; 6,124,421; and 6,303,733 incorporated herein in their entireties may be used in the present invention.

Preferred thermally degradable polymers are polyacenaphthylene homopolymers, polyacenaphthylene copolymers, and polynorbornene derivatives. The more preferred thermally degradable polymers are polyacenaphthylene homopolymers and polyacenaphthylene copolymers. The most preferred thermally degradable polymers are polyacenaphthylene homopolymers.

The preferred thermally degradable polymers may be processed or treated so that after holding for one hour at 300° C., the thermally degradable polymer's weight loss is lower. Such treatments include pre-treatment such as a 300° C. cure, functionalizing the thermally degradable polymers, or using additives at about 5-15 weight percent such as silane of the following formula

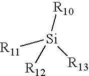

where R₁₀, R₁₁ , R₁₂, and R₁₃ is the same or different and selected from the group consisting of hydrogen, alkyl, aryl, alkoxy, aryloxy, acetoxy, chlorine, or combinations thereof, and where at least one of R₁₀, R₁₁, R₁₂, and R₁₃ is alkoxy, aryloxy, acetoxy, or chlorine; organosiloxanes such as Honeywell's HOSP® product or as taught by commonly assigned U.S. Pat. Nos. 6,043,330 and 6,143,855 or pending patent application 10/161561 filed Jun. 3, 2002; Honeywell ACCUGLASS® T-04 phenysiloxane polymer; Honeywell ACCUGLASS® T-08 methylphenylsiloxane polymer; Honeywell ACCUSPIN® 720 siloxane polymer; hydrogen silsesquioxane as taught by U.S. Pat. Nos. 4,756,977; 5,370,903; and 5,486,564; or methyl silsesquioxane as taught by U.S. Pat. No. 6,143,855, all incorporated herein in their entireties; plus precursors.

Small amounts of thermal stability additives may be used including Si. These additives may form a physical blend with the polymer or react with the polymer.

Adhesion Promoter:

Preferably an adhesion promoter is used with the thermally degradable polymer. The adhesion promoter may be a comonomer reacted with the thermally degradable polymer precursor or an additive to the thermally degradable polymer precursor.

Examples of useful adhesion promoters are disclosed in commonly assigned pending Serial 158513 filed May 30, 2002 incorporated herein in its entirety. The phrase “adhesion promoter” as used herein means any component that when used with the thermally degradable polymer, improves the adhesion thereof to substrates compared with thermally degradable polymers.

Preferably the adhesion promoter is a compound having at least bifunctionality wherein the bifunctionality may be the same or different and at least one of said first functionality and said second functionality is selected from the group consisting of Si containing groups; N containing groups; C bonded to O containing groups; hydroxyl groups; and C double bonded to C containing groups. The phrase “compound having at least bifunctionality” as used herein means any compound having at least two functional groups capable of interacting or reacting, or forming bonds as follows. The functional groups may react in numerous ways including addition reactions, nucleophilic and electrophilic substitutions or eliminations, radical reactions, etc. Further alternative reactions may also include the formation of non-covalent bonds, such as Van der Waals, electrostatic bonds, ionic bonds, and hydrogen bonds.

In the adhesion promoter, preferably at least one of the first functionality and the second functionality is selected from Si containing groups; N containing groups; C bonded to O containing groups; hydroxyl groups; and C double bonded to C containing groups. Preferably, the Si containing groups are selected from Si—H, Si—O, and Si—N; the N containing groups are selected from such as C—NH₂ or other secondary and tertiary amines, imines, amides, and imides; the C bonded to O containing groups are selected from ═CO, carbonyl groups such as ketones and aldehydes, esters, —COOH, alkoxyls having 1 to 5 carbon atoms, ethers, glycidyl ethers; and epoxies; the hydroxyl group is phenol; and the C double bonded to C containing groups are selected from allyl and vinyl groups. For semiconductor applications, the more preferred functional groups include the Si containing groups; C bonded to O containing groups; hydroxyl groups; and vinyl groups.

An example of a preferred adhesion promoter having Si containing groups is silanes of the Formula I: (R₁₄)ₖ(R₁₅)ₗSi(R₁₆)ₘ(R₁₇)ₙ wherein R₁₄, R₁₅, R₁₆, and R₁₇ each independently represents hydrogen, hydroxyl, unsaturated or saturated alkyl, substituted or unsubstituted alkyl where the substituent is amino or epoxy, saturated or unsaturated alkoxyl, unsaturated or saturated carboxylic acid radical, or aryl; at least two of R₁₄, R₁₅, R₁₆, and R₁₇ represent hydrogen, hydroxyl, saturated or unsaturated alkoxyl, unsaturated alkyl, or unsaturated carboxylic acid radical; and k+l+m+n≦4. Examples include vinylsilanes such as H₂C═CHSi(CH₃)₂H and H₂C═CHSi(R₁₈)₃ where R₁₈ is CH₃O, C₂H₅O, AcO, H₂C═CH, or H₂C═C(CH₃)O—, or vinylphenylmethylsilane; allylsilanes of the formula H₂C═CHCH₂—Si(OC₂H₅)₃ and H₂C═CHCH₂—Si(H)(OCH₃)₂; glycidoxypropylsilanes such as (3-glycidoxypropyl)methyidiethoxysilane and (3-glycidoxypropyl)trimethoxysilane; methacryloxypropylsilanes of the formula H₂C═(CH₃)COO(CH₂)₃—Si(OR₁₉)₃ where R₁₉ is an alkyl, preferably methyl or ethyl; aminopropylsilane derivatives including H₂N(CH₂)₃Si(OCH₂CH₃)₃, H₂N(CH₂)₃Si(OH)₃ or H₂N(CH₂)₃OC(CH₃)₂CH═CHSi(OCH₃)₃. The aforementioned silanes are commercially available from Gelest.

An example of a preferred adhesion promoter having C bonded to O containing groups is glycidyl ethers including but not limited to 1,1,1-tris-(hydroxyphenyl)ethane tri-glycidyl ether which is commercially available from TriQuest.

An example of a preferred adhesion promoter having C bonded to O containing groups is esters of unsaturated carboxylic acids containing at least one carboxylic acid group. Examples include trifunctional methacrylate ester, trifunctional acrylate ester, trimethylolpropane triacrylate, dipentaerythritol pentaacrylate, and glycidyl methacrylate. The foregoing are all commercially available from Sartomer.

An example of a preferred adhesion promoter having vinyl groups is vinyl cyclic pyridine oligomers or polymers wherein the cyclic group is pyridine, aromatic, or heteroaromatic. Useful examples include but not limited to 2-vinylpyridine and 4-vinylpyridine, commercially available from Reilly; vinyl aromatics; and vinyl heteroaromatics including but not limited to vinyl quinoline, vinyl carbazole, vinyl imidazole, and vinyl oxazole.

An example of a preferred adhesion promoter having Si containing groups is the polycarbosilane disclosed in commonly assigned copending allowed U.S. patent application Ser. No. 09/471299 filed Dec. 23, 1999 incorporated herein by reference in its entirety. The polycarbosilane is of the Formula II:

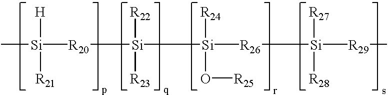

in which R₂₀, R₂₆, and R₂₉ each independently represents substituted or unsubstituted alkylene, cycloalkylene, vinylene, allylene, or arylene; R₂₁, R₂₂, R₂₃, R₂₄, R₂₇, and R₂₈ each independently represents hydrogen atom or organo group comprising alkyl, alkylene, vinyl, cycloalkyl, allyl, or aryl and may be linear or branched; R₂₅ represents organosilicon, silanyl, siloxyl, or organo group; and p, q, r, and s satisfy the conditions of [4≦p+q+r+s≦100,000], and q and r and s may collectively or independently be zero. The organo groups may contain up to 18 carbon atoms but generally contain from about 1 to about 10 carbon atoms. Useful alkyl groups include —CH₂— and —(CH₂)ₜ— where t>1.

Preferred polycarbosilanes of the present invention include dihydrido polycarbosilanes in which R₂₀ is a substituted or unsubstituted alkylene or phenyl, R₂₁ group is a hydrogen atom and there are no appendent radicals in the polycarbosilane chain; that is, q, r, and s are all zero. Another preferred group of polycarbosilanes are those in which the R₂₁, R₂₂, R₂₃, R₂₄, R₂₅, and R₂₈ groups of Formula II are substituted or unsubstituted alkenyl groups having from 2 to 10 carbon atoms. The alkenyl group may be ethenyl, propenyl, allyl, butenyl or any other unsaturated organic backbone radical having up to 10 carbon atoms. The alkenyl group may be dienyl in nature and includes unsaturated alkenyl radicals appended or substituted on an otherwise alkyl or unsaturated organic polymer backbone. Examples of these preferred polycarbosilanes include dihydrido or alkenyl substituted polycarbosilanes such as polydihydridocarbosilane, polyallylhydrididocarbosilane and random copolymers of polydihydridocarbosilane and polyallylhydridocarbosilane.

In the more preferred polycarbosilanes, the R₂₁ group of Formula II is a hydrogen atom and R₂₁ is methylene and the appendent radicals q, r, and s are zero. Other preferred polycarbosilane compounds of the invention are polycarbosilanes of Formula II in which R₂₁ and R₂₇ are hydrogen, R₂₀ and R₂₉ are methylene, and R₂₈ is an alkenyl, and appendent radicals q and r are zero. The polycarbosilanes may be prepared from well known prior art processes or provided by manufacturers of polycarbosilane compositions. In the most preferred polycarbosilanes, the R₂₁ group of Formula II is a hydrogen atom; R₂₄ is —CH₂—; q, r, and s are zero and p is from 5 to 25. These most preferred polycarbosilanes may be obtained from Starfire Systems, Inc. Specific examples of these most preferred polycarbosilanes follow:

| | | | Peak |
|---|---|---|---|
| | Weight Average | | Molecular |
| | Molecular Weight | | Weight |
| Polycarbosilane | (Mw) | Polydispersity | (Mp) |
| 1 | 400-1,400 | 2-2.5 | 330-500 |
| 2 | 330 | 1.14 | 320 |
| 3 (with 10% allyl groups) | 10,000-14,000 | 10.4-16 | 1160 |
| 4 (with 75% allyl groups) | 2,400 | 3.7 | 410 |

As can be observed in Formula II, the polycarbosilanes utilized in the subject invention may contain oxidized radicals in the form of siloxyl groups when r>0. Accordingly, R₂₆. represents organosilicon, silanyl, siloxyl, or organo group when r>0. It is to be appreciated that the oxidized versions of the polycarbosilanes (r>0) operate very effectively in, and are well within the purview of the present invention. As is equally apparent, r can be zero independently of p, q, and s the only conditions being that the radicals p, q, r, and s of the Formula II polycarbosilanes must satisfy the conditions of [4<p+q+r+s<100,000], and q and r can collectively or independently be zero.

The polycarbosilane may be produced from starting materials that are presently commercially available from many manufacturers and by using conventional polymerization processes. As an example of synthesis of the polycarbosilanes, the starting materials may be produced from common organo silane compounds or from polysilane as a starting material by heating an admixture of polysilane with polyborosiloxane in an inert atmosphere to thereby produce the corresponding polymer or by heating an admixture of polysilane with a low molecular weight carbosilane in an inert atmosphere to thereby produce the corresponding polymer or by heating an admixture of polysilane with a low molecular carbosilane in an inert atmosphere and in the presence of a catalyst such as polyborodiphenylsiloxane to thereby produce the corresponding polymer. Polycarbosilanes may also be synthesized by Grignard Reaction reported in U.S. Pat. No. 5,153,295 hereby incorporated by reference.

An example of a preferred adhesion promoter having hydroxyl groups is phenol-formaldehyde resins or oligomers of the Formula IlIl:—[R₃₀C₆H₂(OH)(R₃₁)]ᵤ— where R₃₀ is substituted or unsubstituted alkylene, cycloalkylene, vinyl, allyl, or aryl; R₃₁, is alkyl, alkylene, vinylene, cycloalkylene, allylene, or aryl; and u=3-100. Examples of useful alkyl groups include —CH₂— and —(CH₂)ᵥ— where v>1. A particularly useful phenol-formaldehyde resin oligomer has a molecular weight of 1500 and is commercially available from Schenectady International Inc.

The present adhesion promoter is added in small, effective amounts preferably from about 1% to about 10% and more preferably from about 2% to about 7% based on the weight of the present thermally degradable polymer.

Gas Layer Formation:

The term “degrade” as used herein refers to the breaking of covalent bonds. Such breaking of bonds may occur in numerous ways including heterolytic and homolytic breakage. The breaking of bonds need not be complete, i.e., not all breakable bonds must be cleaved. Furthermore, the breaking of bonds may occur in some bonds faster than in others. Ester bonds, for example, are generally less stable than amide bonds, and therefore, are cleaved at a faster rate. Breakage of bonds may also result in the release of fragments differing from one another, depending on the chemical composition of the degraded portion.

In the gas layer formation process, the thermally degradable polymer is applied to a substrate (described below), and baked, and may be cured. If the preferred thermally degradable polymer is thermoplastic, curing may not be necessary. However, if the preferred thermally degradable polymer is thermoset, curing will be necessary. After application of the present composition to an electronic topographical substrate, the coated structure is subjected to a bake and cure thermal process at increasing temperatures ranging from about 50° C. up to about 350° C. to polymerize the coating. The curing temperature is at least about 300° C. because a lower temperature is insufficient to complete the reaction herein. If a non-thermal decomposition technique is used, a higher curing temperature may be used. Curing may be carried out in a conventional curing chamber such as an electric furnace, hot plate, and the like and is generally performed in an inert (non-oxidizing) atmosphere (nitrogen) in the curing chamber. In addition to furnace or hot plate curing, the present compositions may also be cured by exposure to ultraviolet radiation, microwave radiation, or electron beam radiation as taught by commonly assigned patent publication PCT/US96/08678 and U.S. Pat. Nos. 6,042,994; 6,080,526; 6,177,143; and 6,235,353, which are incorporated herein by reference in their entireties. Any non oxidizing or reducing atmospheres (e.g., argon, helium, hydrogen, and nitrogen processing gases) may be used in the practice of the present invention, if they are effective to conduct curing of the present polymer. If crosslinked polymers are to be used, the polymerization may occur with or without added thermal or photo-initiators and in the B-staging process or during the spin/bake/cure process.

Thermal energy is applied to the cured polymer to substantially degrade or decompose the thermally degradable polymer into its starting components or monomers. As used herein, “substantially degrade” preferably means at least 80 weight percent of the thermally degradable polymer degrades or decomposes. For the preferred polyacenaphthylene based homopolymer or copolymer thermally degradable polymer, we have found by using analytical techniques such as Thermal Desorption Mass Spectroscopy that the thermally degradable polymer degrades, decomposes, or depolymerizes into its starting components of acenaphthylene monomer and comonomer. Thermal degradation may be assisted with other forms of physical energy including but not limited to microwave, sonics, UV radiation, electron beam, infrared radiation, and x-ray.

Thermal energy is also applied to volatilize the substantially degraded or decomposed thermally degradable polymer out of the thermosetting component matrix. Preferably, the same thermal energy is used for both the degradation and volatilization steps. As the amount of volatilized degraded porogen increases, the resulting porosity of the microelectronic device increases.

Preferably, the cure temperature used for dielectric layers adjacent to the gas layer will also substantially degrade the thermally degradable polymer and volatilize it. Typical cure temperature and conditions will be described in the Utility section below.

The formed gas layer preferably has a thickness of about 0.1 to about 2 microns. A microelectronic device may have more than one gas layer present.

Alternatively, other procedures or conditions which at least partially remove the polymer without adversely affecting the remainder of the semiconductor device may be used. Preferably, the polymer is substantially removed. Typical removal methods include, but are not limited to, exposure to radiation, such as but not limited to, electromagnetic radiation such as ultraviolet, x-ray, laser, or infrared radiation; mechanical energy such as sonication or physical pressure; particle radiation such as gamma ray, alpha particles, neutron beam, or. electron beam; solvent extraction/dissolution including vapor phase processing and supercritical fluids; or chemical etching including gas, vapor, supercritical fluid-carried etchants.

Utility:

The present invention may be used in an interconnect associated with a single integrated circuit (“IC”) chip. An integrated circuit chip typically has on its surface a plurality of layers of the present composition and multiple layers of metal conductors. It may also include regions of the present composition between discrete metal conductors or regions of conductor in the same layer or level of an integrated circuit.

Substrates contemplated herein may comprise any desirable substantially solid material. Particularly desirable substrate layers comprise films, glass, ceramic, plastic, metal or coated metal, or composite material. In preferred embodiments, the substrate comprises a silicon or gallium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and its oxides), a polymer-based packaging or board interface such as found in a polyimide-based flex package, lead or other metal alloy solder ball surface, glass and polymers. Useful substrates include silicon, silicon nitride, silicon oxide, silicon oxycarbide, silicon dioxide, silicon carbide, silicon oxynitride, titanium nitride, tantalum nitride, tungsten nitride, aluminum, copper, tantalum, organosiloxanes, organo silicon glass, and fluorinated silicon glass. In other embodiments, the substrate comprises a material common in the packaging and circuit board industries such as silicon, copper, glass, and polymers. The present compositions may also be used as a dielectric substrate material in microchips and multichip modules.

The present invention may be used in dual damascene (such as copper) processing and substractive metal (such as aluminum or aluminum/tungsten) processing for integrated circuit manufacturing. The present composition may be used in a desirable all spin-on stacked film as taught by Michael E. Thomas, Ph.D., “Spin-On Stacked Films for Low k_{eff} Dielectrics”, Solid State Technology (July 2001), incorporated herein in its entirety by reference. Known dielectric materials such as inorganic, organic, or organic and inorganic hybrid materials may be used in the present invention. Examples include phenylethynylated-aromatic monomer or oligomer; fluorinated or non-fluorinated poly(arylene ethers) such as taught by commonly assigned U.S. Pat. Nos. 5,986,045; 6,124,421; 6,291,628 and 6,303,733; bisbenzocyclobutene; and organosiloxanes such as taught by commonly assigned U.S. Pat. No. 6,143,855 and pending U.S. patent application Ser. No. 10/078,919 filed Feb. 19, 2002 and 10/161561 filed Jun. 3, 2002; Honeywell International Inc.'s commercially available HOSP® product; nanoporous silica such as taught by commonly assigned U.S. Pat. No. 6,372,666; Honeywell International Inc.'s commercially available NANOGLASS® E product; organosilsesquioxanes taught by commonly assigned WO 01/29052; and fluorosilsesquioxanes taught by commonly U.S. Pat. No. 6,440,550, incorporated herein in their entireties. Other useful dielectric materials are disclosed in commonly assigned pending patent applications PCT/US01/22204 filed Oct. 17, 2001 (claiming the benefit of our commonly assigned pending patent applications U.S. Ser. No. 09/545058 filed Apr. 7, 2000; U.S. Ser. No. 09/618945 filed Jul. 19, 2000; U.S. Ser. No. 09/897936 filed Jul. 5, 2001; and U.S. Ser. No. 09/902924 filed Jul. 10, 2001; and International Publication WO 01/78110 published Oct. 18, 2001); PCT/US01/50812 filed Dec. 31, 2001; 60/384304 filed May 30, 2002; 60/347195 filed Jan. 8, 2002 and 60/384303 filed May 30, 2002; 60/350187 filed Jan. 15, 2002 and 10/160773 filed May 30, 2002; and 10/158513 filed May 30, 2002 and 10/158548 filed May 30, 2002, which are incorporated herein by reference in their entireties. These dielectric materials may be used as etch stops and hard masks. Bottom anti-reflective coatings that may be used in the present invention are Honeywell International Inc.'s commercially available DUO™ bottom anti-reflective coating materials and taught by commonly assigned U.S. Pat. Nos. 6,248,457; 6,365,765; and 6,368,400.

Analytical Test Methods:

Differential Scanning Calorimetry (DSC): DSC measurements were performed using a TA Instruments 2920 Differential Scanning Calorimeter in conjunction with a controller and associated software. A standard DSC cell with temperature ranges from 250° C. to 725° C. (inert atmosphere: 50 ml/min of nitrogen) was used for the analysis. Liquid nitrogen was used as a cooling gas source. A small amount of sample (10-12 mg) was carefully weighed into an Auto DSC aluminum sample pan (Part # 990999-901) using a Mettler Toledo Analytical balance with an accuracy of ±0.0001 grams. Sample was encapsulated by covering the pan with the lid that was previously punctured in the center to allow for outgasing. Sample was heated under nitrogen from 0° C. to 450° C. at a rate of 100° C./minute (cycle 1), then cooled to 0° C. at a rate of 100° C./minute. A second cycle was run immediately from 0° C. to 450° C. at a rate of 100° C./minute (repeat of cycle 1). The cross-linking temperature was determined from the first cycle.

Glass Transition Temperature (Tg): The glass transition temperature of a thin film was determined by measuring the thin film stress as a function of temperature. The thin film stress measurement was performed on a KLA 3220 Flexus. Before the film measurement, the uncoated wafer was annealed at 500° C. for 60 minutes to avoid any errors due to stress relaxation in the wafer itself. The wafer was then deposited with the material to be tested and processed through all required process steps. The wafer was then placed in the stress gauge, which measured the wafer bow as function of temperature. The instrument calculated the stress versus temperature graph, provided that the wafer thickness and the film thickness were known. The result was displayed in graphic form. To determine the Tg value, a horizontal tangent line was drawn (a slope value of zero on the stress vs. temperature graph). Tg value was where the graph and the horizontal tangent line intersect.

It should be reported if the Tg was determined after the first temperature cycle or a subsequent cycle where the maximum temperature was used because the measurement process itself may influence Tg.

Isothermal Gravimetric Analysis (ITGA) Weight Loss: Total weight loss was determined on the TA Instruments 2950 Thermogravimetric Analyzer (TGA) used in conjunction with a TA Instruments thermal analysis controller and associated software. A Platinel II Thermocouple and a Standard Furnace with a temperature range of 25° C. to 1000° C. and heating rate of 0.1° C. to 100° C./min were used. A small amount of sample (7 to 12 mg) was weighed on the TGA's balance (resolution: 0.1 g; accuracy: to ±0.1%) and heated on a platinum pan. Samples were heated under nitrogen with a purge rate of 100 ml/min (60 ml/min going to the furnace and 40 ml/min to the balance). Sample was equilibrated under nitrogen at 20° C. for 20 minutes, then temperature was raised to 200° C. at a rate of 10° C./minute and held at 200° C. for 10 minutes. The weight loss was calculated.

Refractive Index: The refractive index measurements were performed together with the thickness measurements using a J. A. Woollam M-88 spectroscopic ellipsometer. A Cauchy model was used to calculate the best fit for Psi and Delta. Unless noted otherwise, the refractive index was reported at a wavelenth of 633 nm (details on Ellipsometry can be found in e.g. “Spectroscopic Ellipsometry and Reflectometry” by H. G. Thompkins and William A. McGahan, John Wiley and Sons, Inc., 1999).

Modulus and Hardness: Modulus and hardness were measured using instrumented indentation testing. The measurements were performed using a MTS Nanoindenter XP (MTS Systems Corp., Oak Ridge, Tenn.). Specifically, the continuous stiffness measurement method was used, which enabled the accurate and continuous determination of modulus and hardness rather than measurement of a discrete value from the unloading curves. The system was calibrated using fused silica with a nominal modulus of 72+−3.5 GPa. The modulus for fused silica was obtained from average value between 500 to 1000 nm indentation depth. For the thin films, the modulus and hardness values were obtained from the minimum of the modulus versus depth curve, which is typically between 5 to 15% of the film thickness.

Coefficient of Thermal Expansion: The instruments used were 1) SVG Spin coater, to spin coat and bake films; 2) Cosmos Furnace, cure wafers; 3) Woollam M-88 ellipsometer, post bake and cure thickness measurement; and 4) Tencor FLX-2320 (stress gauge): stress temperature and CTE measurement. Two different substrates are required for CTE measurement. In this case, Silicon (Si) and Gallium Arsenide (GaAs) substrates were used. Wafers of Si and GaAs substrate were subjected to a furnace anneal at 500° C. for 60 minutes. Room temperature background stress measurement was taken for both substrates after furnace anneal. The film was coated on the pre-annealed wafers on SVG spin coater with subsequent bake on hot plate at 125° C., 200° C., and 350° C. each for 60 seconds. Post bake thickness and RI measurements were performed on the Woollam ellipsometer. Wafers were cured using the Cosmos furnace R-4 at 400° C. for 60 minutes. Post cure thickness and RI measurements were taken on the Woollam ellipsometer. Stress temperature measurements were performed on the FLX-2320. It is important to have a constant temperature ramp rate for stress temperature measurement. The temperature was ramped to from room temperature to 450° C. at 5° C./min.

Data analysis was performed using the analysis software on the FLX-2320 system. From the stress-temperature data files, two graphs were created, one for each substrate. File path and name were copied on the Elastic and Expansion display from the analysis menu. Both files are copied on the Elastic and Expansion display. The CTE calculation was done using the FLX-2320 software, which uses the following relationship:

dσ/dT=(E/(1−υ) )_{f}(αₛ−α_{f})

where dσ/dT is the derivative of stress versus temperature (measured);

(E/(1−υ) )_{f} is the biaxial modulus of the film (unknown);

αₛ is the substrate thermal expansion coefficient (known); and

α_{f} is the film thermal expansion coefficient (unknown)

The average CTE and biaxial modulus of the film and the Si and GaAs substrates were displayed in a dialog box. Film values were reported as CTE and biaxial modulus values.

Thermal Desorption Mass Spectroscopy: Thermal Desorption Mass Spectroscopy (TDMS) is used to measure the thermal stability of a material by analyzing the desorbing species while the material is subjected to a thermal treatment.

The TDMS measurement was performed in a high vacuum system equipped with a wafer heater and a mass spectrometer, which was located close to the front surface of the wafer. The wafer was heated using heating lamps, which heat the wafer from the backside. The wafer temperature was measured by a thermocouple, which was in contact with the front surface of the wafer. Heater lamps and thermocouple were connected to a programmable temperature controller, which allowed several temperature ramp and soak cycles. The mass spectrometer was a Hiden Analytical HAL IV RC RGA 301. Both mass spectrometer and the temperature controller were connected to a computer, which read and recorded the mass spectrometer and the temperature signal versus time.

To perform TDMS analysis, the material was first deposited as a thin film onto an 8 inch wafer using standard processing methods. The wafer was then placed in the TDMS vacuum system and the system was pumped down to a pressure below 1e−7 torr. The temperature ramp was then starting using the temperature controller. The temperature and the mass spectrometer signal were recorded using the computer. For a typical measurement with a ramp rate of about 10 degree C. per minute, one complete mass scan and one temperature measurement are recorded every 20 seconds. The mass spectrum at a given time and temperature at a given time can be analyzed after the measurement is completed.

Average Pore Size Diameter: The N₂ isotherms of porous samples was measured on a Micromeretics ASAP 2000 automatic isothermal N₂ sorption instrument using UHP (ultra high purity industrial gas) N₂, with the sample immersed in a sample tube in a liquid N₂ bath at 77° K.

For sample preparation, the material was first deposited on silicon wafers using standard processing conditions. For each sample, three wafers were prepared with a film thickness of approximately 6000 Angstroms. The films were then removed from the wafers by scraping with a razor blade to generate powder samples. These powder samples were pre-dried at 180° C. in an oven before weighing them, carefully pouring the powder into a 10 mm inner diameter sample tube, then degassing at 180 ° C. at 0.01 Torr for>3 hours.

The adsorption and desorption N₂ sorption was then measured automatically using a 5 second equilibration interval, unless analysis showed that a longer time was required. The time required to measure the isotherm was proportional to the mass of the sample, the pore volume of the sample, the number of data points measured, the equilibration interval, and the P/Po tolerance. (P is the actual pressure of the sample in the sample tube. Po is the ambient pressure outside the instrument.) The instrument measures the N₂ isotherm and plots N₂ versus P/Po.

The apparent BET (Brunauer, Emmett, Teller method for multi-layer gas absorption on a solid surface disclosed in S. Brunauer, P. H. Emmett, E. Teller; J. Am. Chem. Soc. 60, 309-319 (1938)) surface area was calculated from the lower P/Po region of the N2 adsorption isotherm using the BET theory, using the linear section of the BET equation that gives an R² fit>0.9999.

The pore volume was calculated from the volume of N₂ adsorbed at the relative pressure P/Po value, usually P/Po^{˜}0.95, which is in the flat region of the isotherm where condensation is complete, assuming that the density of the adsorbed N₂ is the same as liquid N₂ and that all the pores are filled with condensed N₂ at this P/Po.

The pore size distribution was calculated from the adsorption arm of the N₂ isotherm using the BJH (E. P. Barret, L. G. Joyner, P. P. Halenda; J. Am. Chem. Soc., 73, 373-380 (1951)) theory. This uses the Kelvin equation, which relates curvature to suppression of vapor pressure, and the Halsey equation, which describes the thickness of the adsorbed N₂ monolayer versus P/Po, to convert the volume of condensed N₂ versus P/Po to the pore volume in a particular range of pore sizes.

The average cylindrical pore diameter D was the diameter of a cylinder that has the same apparent BET surface area Sa (m²/g) and pore volume Vp (cc/g) as the sample, so D (nm)=4000 Vp/Sa.

Comparative:

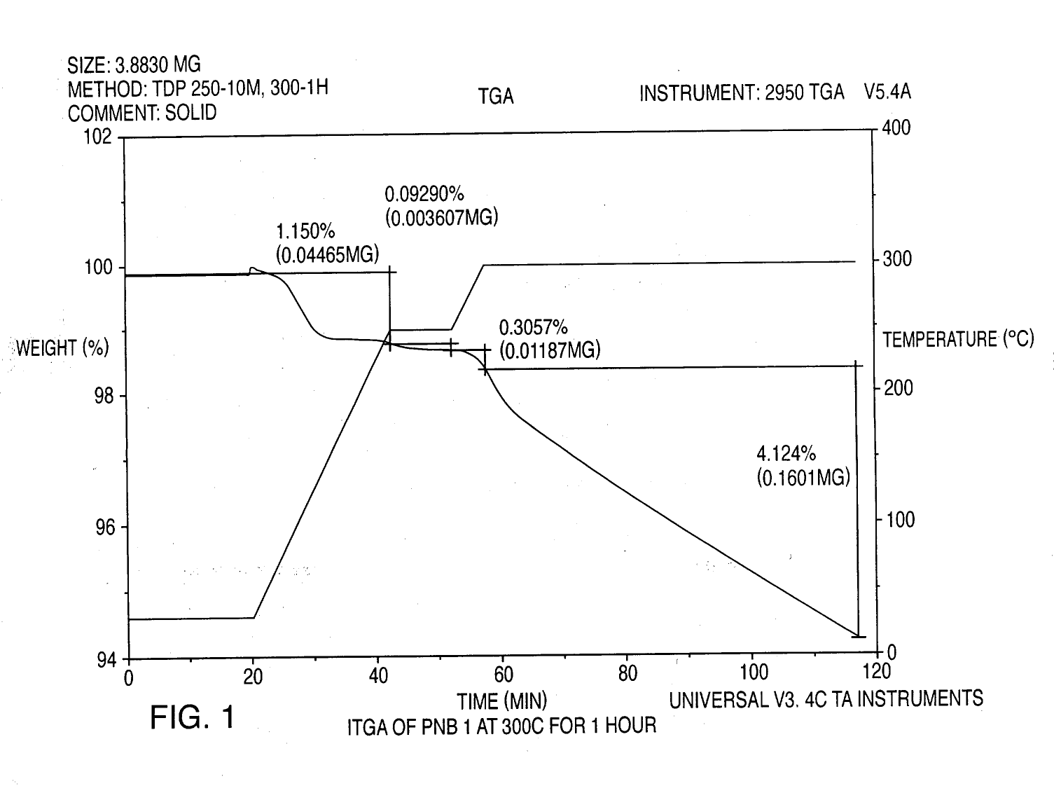

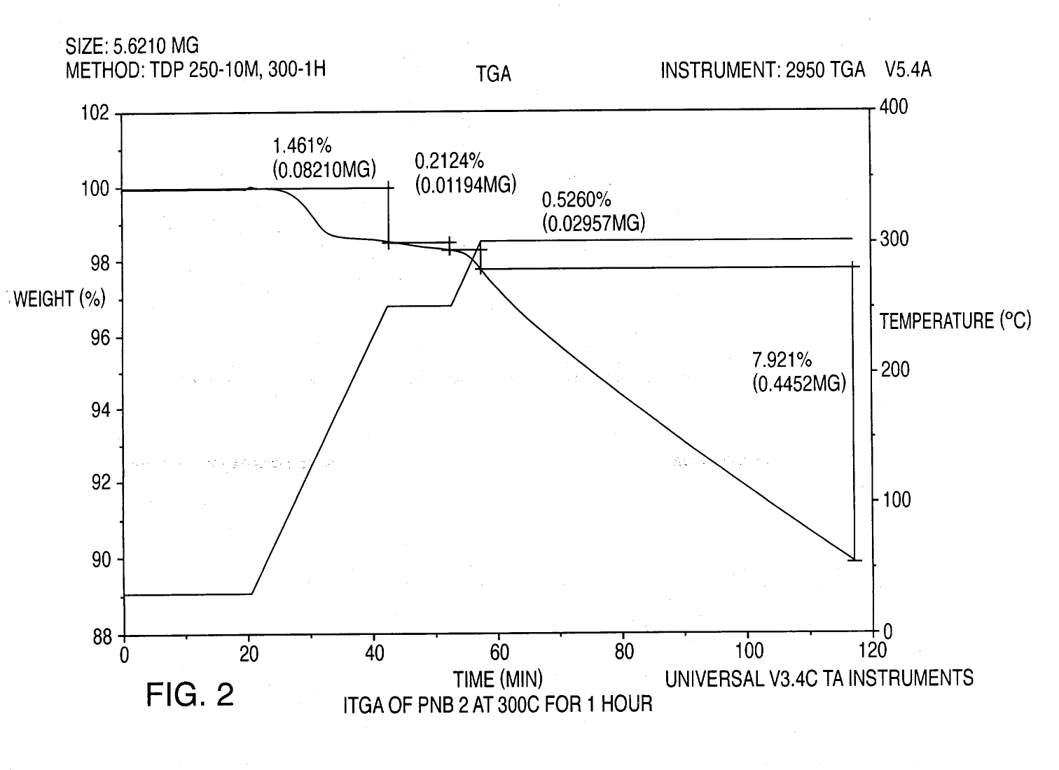

Hollie Reed et al., “Porous Dielectrics and Air-Gaps Created by Sacrificial Placeholders”, International SEMATECH Ultra Low k Workshop (Jun. 6-7, 2002) discloses polynorbornene copolymers of the following formula

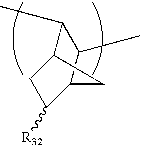

where R₃₂ is alkyl or triethoxysilyl. The properties of such polynorbornene copolymers are set forth in the following Table 3 and FIGS. 1 and 2.

TABLE 3

| PROPERTY | DETAILS | PNB 1 | PNB 2 |
|---|---|---|---|
| Wt loss % | 0-250° C. | 1.150 | 1.461 |
| Ramp 1 | 250° C. for 10 minutes | 00.0929 | 0.2124 |
| | 250-300° C. | 0.3057 | 0.526 |
| | 300° C. for 1 hour | 4.124 | 7.921 |
| Wt loss % | 0-250° C. | 1.19 | 1.572 |
| Ramp 2 | 250° C. for 10 minutes | 0.01 | 0.08 |
| | 250-425° C. | 28.99 | 29.81 |
| | 425° C. for 1 hour | 67.79 | 660.36 |
| | Total | 97.98 | 97.822 |

PNB 1 was applied to a Si-based substrate and baked. The baked film had the properties in the following Table 4:

TABLE 4

| PROPERTY | PNB 1 | PNB2 |
|---|---|---|
| Thickness (Angstroms) | 5108.80 | 5512.41 |
| Refractive Index | 1 .5752 | 1 .5676 |
| (@ 633 nm) | | |
| Film Quality | Good | Good |
| Modulus (Gpa) | 7.000 | 7.078 |
| Hardness (Gpa) | 0.371 | 0.374 |

The preceding was repeated except that PNB 2 instead of PNB 1 was used.

PNB 1 above was applied to an oxide based substrate. The applied material was baked (150° C., 250° C., 350° C. at one minute each) and then degraded (425° C./one hour). The baked film had the properties in the following Table 5:

TABLE 5

| PROCESSING | PROPERTY | PNB1 | PNB2 |
|---|---|---|---|
| Post Bake | Thickness | 4726.9 | 8572.3 |
| | Index (@ 633 nm) | 1.5972 | 1.6019 |
| | SiO₂ | — | — |
| Film Quality | Visual | Good | Good |
| Post Degradation | Thickness | 1971.5 | 3781.6 |
| | Index (@ 633 nm) | 1.8184 | 1.7839 |
| | SiO₂ | — | — |
| | Conductivity | Not detectable | Not detectable |
| | (4 point probe) | | |

### INVENTIVE EXAMPLE 1

### Preparation of Copolymer of Acenaphthylene and Vinyl Pivalate

A thermally degradable polymer comprising copolymer of acenaphthylene and vinyl pivalate was made as follows. To a 250-milliliter flask equipped with a magnetic stirrer were added 20 grams of technical grade acenaphthylene, 3.1579 grams (0.0246 mole) of vinyl pivalate, 0.5673 gram (2.464 millimole) of di-tert-butyl azodicarboxylate and 95 milliliters of xylenes. The mixture was stirred at room temperature for ten minutes until a homogeneous solution was obtained. The reaction solution was then degassed at reduced pressure for five minutes and purged with nitrogen. This process was repeated three times. The reaction mixture was then heated to 140° C. for six hours under nitrogen. The solution was cooled to room temperature and added into 237 milliliters of ethanol dropwise. The mixture was kept stirring at room temperature for another 20 minutes. The precipitate that formed was collected by filtration and dried under vacuum. The resulting copolymer properties are listed as Copolymer 18 in Table 2 above. Other thermally degrabable polymers comprising copolymers of acenaphthylene and vinyl pivalate were prepared in a similar manner but varying the comonomer percentage used, initiator type and percentage used, and reaction time and temperature as set forth in Table 2 above.

A layer is made from Copolymer 1 from Table 2 and baked. At the appropriate time in the integration scheme, the baked layer is decomposed and the decomposed layer is volatilized to form a gas layer. The preceding is repeated for each copolymer of Table 2.

### INVENTIVE EXAMPLE 2

### Preparation of Copolymer of Acenaphthylene and Tert-butyl Acrylate

A thermally degradable polymer comprising copolymer of acenaphthylene and tert-butylacrylate was made as follows. To a 250-milliliter flask equipped with a magnetic stirrer were added 20 grams of technical grade acenaphthylene, 2.5263 grams (0.01971 mole) of tert-butyl acrylate, 0.3884 gram (2.365 millimole) of 2,2′-azobisisobutyronitrile, and 92 milliliters xylenes. The mixture was stirred at room temperature for 10 minutes until a homogeneous solution was obtained. The reaction solution was then degassed at reduced pressure for 5 minutes and purged with nitrogen. This process was repeated three times. The reaction mixture was then heated to 70° C. for 24 hours under nitrogen. The solution was cooled to room temperature and added into 230 milliliters of ethanol dropwise. The mixture was kept stirring at room temperature for another 20 min. The precipitate that formed was collected by filtration and dried under vacuum. The resulting copolymer properties are listed as Copolymer 2 in Table 2 above. Other thermally degradable polymer comprising copolymers of acenaphthylene and tert-butylacrylate were prepared in a similar manner but varying the comonomer percentage used, initiator type and percentage used, and reaction time and temperature as set forth in Table 2 above.

### INVENTIVE EXAMPLE 3

### Preparation of Copolymer of Acenaphthylene and Vinyl Acetate

A thermally degradable polymer comprising copolymer of acenaphthylene and vinyl acetate was made as follows. To a 250-milliliter flask equipped with a magnetic stirrer were added 20 grams of technical grade acenaphthylene, 1.6969 grams (0.01971 mole) of vinyl acetate, 0.3884 gram (2.365 millimole) of 2,2′-azobisisobutyronitrile and 88 milliliters xylenes. The mixture was stirred at room temperature for 10 minutes until a homogeneous solution was obtained. The reaction solution was then degassed at reduced pressure for 5 minutes and purged with nitrogen. This process was repeated three times. The reaction mixture was then heated to 70° C. for 24 hours under nitrogen. The solution was cooled to room temperature and added into 220 milliliters of ethanol dropwise. The mixture was kept stirring at room temperature for another 20 minutes. The precipitate that formed was collected by filtration and dried under vacuum. The resulting copolymer properties are listed as Copolymer 18 in Table 2 above. Another thermally degradable polymer comprising copolymers of acenaphthylene and vinyl acetate was prepared in a similar manner but varying the comonomer percentage used; the resulting copolymer properties are listed as Copolymer 19 in Table 2 above.

### INVENTIVE EXAMPLE 4

### Preparation of Polyacenaphthylene Homopolymer

A polymer of acenaphthylene was made as follows. To a 250-milliliter flask equipped with a magnetic stirrer were added 30 grams of technical grade acenaphthylene, 0.3404 gram of di-tert-butyl azodicarboxylate (1.478 millimole) and 121 milliliters xylenes. The mixture was stirred at room temperature for 10 minutes until a homogeneous solution was obtained. The reaction solution was then degassed at reduced pressure for five minutes and purged with nitrogen. This process was repeated three times. The reaction mixture was then heated to 140° C. for six hours under nitrogen. The solution was cooled to room temperature and added into 303 milliliters of ethanol dropwise. The mixture was kept stirring at room temperature for another 20 minutes. The precipitate that formed was collected by filtration and dried under vacuum. The resulting homopolymer properties are listed as Homopolymer 1 in Table 6 below where DBADC stands for di-tert-butyl azodicarboxylate and PDI stands for polydispersion index (Mw/Mn). Other thermally degradable polymers comprising polyacenaphthylene homopolymer were prepared in a similar manner but varying the initiator type and percentage used and the reaction time and temperature as set forth in table 6 where below AIBN stands for 2,2′-azobisisobutyronitrile.

TABLE 6

| | Initiator | | | | | | | |
|---|---|---|---|---|---|---|---|---|
| Homopolymer | Type | Initiator % | Solvent | Temp. (C.) | Time (hr) | Mn | Mw | PDI |
| 1 | DBADC | 1% | Xylene | 140 | 6 | 3260 | 14469 | 4.44 |
| 2 | DBADC | 2% | Xylene | 140 | 6 | 2712 | 11299 | 4.17 |
| 3 | DBADC | 3% | Xylene | 140 | 6 | 3764 | 14221 | 3.78 |
| 4 | DBADC | 4% | Xylene | 140 | 6 | 3283 | 8411 | 2.56 |
| 5 | DBADC | 6% | Xylene | 140 | 6 | 2541 | 7559 | 2.97 |
| 6 | DBADC | 8% | Xylene | 140 | 6 | 2260 | 6826 | 3.02 |
| 7 | DBADC | 12% | Xylene | 140 | 6 | 2049 | 5805 | 2.83 |
| 8 | DBADC | 16% | Xylene | 140 | 6 | 2082 | 5309 | 2.55 |
| 9 | DBADC | 20% | Xylene | 140 | 6 | 1772 | 4619 | 2.61 |
| 10 | DBADC | 30% | Xylene | 140 | 6 | 1761 | 3664 | 2.08 |
| 11 | AIBN | 2% | Xylene | 70 | 24 | 3404 | 7193 | 2.11 |
| 12 | AIBN | 2% | Xylene | 70 | 24 | 3109 | 6141 | 1.98 |
| 13 | AIBN | 2% | Xylene | 70 | 24 | 3500 | 7295 | 2.08 |
| 14 | AIBN | 2% | Xylene | 70 | 24 | 3689 | 6165 | 1.67 |

### INVENTIVE EXAMPLE 5

### Preparation of Polyacenaphthylene Homopolymer

To a 2000-mL flask equipped with a magnetic stirrer were added 200 grams of technical grade acenaphthylene, 0.4539 gram (1.917 mmol) of Di-tert-butyl azodicarboxylate, and 800 ml of xylenes. The mixtures was stirred at room temperature for 20 min until a homogeneous solution was obtained. The reaction solution was then degassed at reduced pressure for 5 min and purged with Nitrogen. This process was repeated three times. The reaction mixture was then heated to 140 ° C. for 6 hours under nitrogen with stirring. The solution was cooled to room temperature and added into 2000 mL of ethanol drop-wise. The mixture was kept stirring using an overhead stirrer at room temperature for another 30 min. The precipitate that formed was collected by filtration. The precipitate was then put into 2000 mL of ethanol and the mixture was kept stirring using an overhead stirrer at room temperature for 30 min. The precipitate that formed was collected by filtration. The washing procedure was repeated two more times. The precipitate that formed was collected by filtration and air dried in hood overnight. The air-dried white precipitate was then further dried at 50° C. under reduced pressure.

### INVENTIVE EXAMPLE 6

### Preparation of Polyvinylnorbornene

To a 500-mL flask equipped with a magnetic stirrer were added 50 g of 5-vinyl-2-norbornene (95% pure, this corresponds to 0.3952 mol of pure 5-vinyl-2-norbornene), 0.1298 g (0.7903 mmol) of 2,2′-Azobisisobutyronitrile and 201 ml of xylenes. The mixture was stirred at room temperature for 20 min until a homogeneous solution was obtained. The reaction solution was then degassed at reduced pressure for 5 min and purged with Nitrogen. This process was repeated three times. The reaction mixture was then heated to 70 ° C. for 24 hours under nitrogen with stirring. The solution was cooled to room temperature and added into 500 mL of ethanol drop-wise. The mixture was kept stirring using an overhead stirrer at room temperature for another 30 min. The precipitate that formed was collected by filtration. The precipitate was then put into 500 mL of ethanol and the mixture was kept stirring using an overhead stirrer at room temperature for 30 min. The precipitate that formed was collected by filtration. The washing procedure was repeated one more times. The precipitate that formed was collected by filtration and air dried in hood overnight. The air-dried white precipitate was then further dried at 50 ° C. under reduced pressure.

A layer is made and baked. At an appropriate time in an integration scheme, the baked layer is decomposed and the decomposed layer is volatilized to form a gas layer.

### INVENTIVE EXAMPLE 7

### Preparation of Polynorbornene-co-acenaphthylene

Polynobornene-co-acenaphthylene may be prepared according to the following: April D. Hennis, Jennifer D. Polley, Gregory S. Long, Ayusman Sen, Dmitry Yandulov, John Lipian, Geroge M. Benedikt, and Larry F. Rhodes Organometallics 2001, 20, 2802. To a 500-mL three-neck flask with a magnetic stirrer and nitrogen inlet and outlet are added 25.00 g (0.1468 mol) of 5-phenyl-2-norbornene, 29.80 g of acenaphthylene and 274 ml of dichloromethane (mixture A). The mixture (A) is stirred at room temperature until a homogeneous solution was obtained. To a 65 ml plastic container are added 0.0778 g (0.2937 mmol) of [(1,5-cyclooctadiene)Pd(CH₃)(Cl)], 0.0770 g (0.2937 mmol) of PPh₃, 0.2603 g (0.2937 mmol) of Na[3,5-(CH₃)₂C₆H₃]₄B and 31 ml of dichloromethane (mixture B). The mixture (B) is shaken at room temperature until a homogeneous solution is obtained. The mixture (B) is then added to mixture (A) under nitrogen and the reaction mixture is heated to reflux under nitrogen with vigorously stirring for 24 hours. The solution iss then precipitated in 548 ml of methanol. Polymer is collected by filtration and dried under reduced pressure.

A layer is made and baked. At an appropriate time in an integration scheme, the baked layer is decomposed and the decomposed layer is volatilized to form a gas layer.

### INVENTIVE EXAMPLE 8

### Preparation of Polynorbornene-co-indene

Polynobornene-co-indene may be prepared according to the following. April D. Hennis, Jennifer D. Polley, Gregory S. Long, Ayusman Sen, Dmitry Yandulov, John Lipian, Geroge M. Benedikt, and Larry F. Rhodes Organometallics 2001, 20, 2802. To a 500-mL three-neck flask with a magnetic stirrer and nitrogen inlet and outlet are added 25.00 g (0.1468 mol) of 5-phenyl-2-norbornene, 17.06 g (0.1468 mol) of indene and 210 ml of dichloromethane (mixture A). The mixture (A) is stirred at room temperature until a homogeneous solution was obtained. To a 65 ml plastic container are added 0.0778 g (0.2937 mmol) of [(1,5-cyclooctadiene)Pd(CH₃)(Cl)], 0.0770 g (0.2937 mmol) of PPh₃, 0.2603 g (0.2937 mmol) of Na[3,5-(CH₃)₂C₆H₃]₄B and 31 ml of dichloromethane (mixture B). The mixture (B) is shaken at room temperature until a homogeneous solution is obtained. The mixture (B) is then added to mixture (A) under nitrogen and the reaction mixture is heated to reflux under nitrogen with vigorously stirring for 24 hours. The solution is then precipitated in 420 ml of methanol. Polymer is collected by filtration and dried under reduced pressure.

A layer is made and baked. At an appropriate time in an integration scheme, the baked layer is decomposed and the decomposed layer is volatilized to form a gas layer.

### INVENTIVE EXAMPLE 9

### Preparation of Poly(5-Phenyl-2-Norbornene-co-5-Triethoxysilyl-2-Norbornene-co-Acenaphthylene)

Poly(5-phenyl-2-norbornene-co-5-triethoxysilyl-2-norbornene-co-acenaphthylene) may be prepared by the following: April D. Hennis, Jennifer D. Polley, Gregory S. Long, Ayusman Sen, Dmitry Yandulov, John Lipian, Geroge M. Benedikt, and Larry F. Rhodes Organometallics 2001, 20, 2802. To a 500-mL three-neck flask with a magnetic stirrer and nitrogen inlet and outlet are added 25.00 g (0.1468 mol) of 5-phenyl-2-norbornene, 29.80 g (75% pure, corresponding to 0.1468 mol) of acenaphthylene, 3.77 g (0.01 648 mol) of 5-triethoxysilyl-2-norbornene and 293 ml of dichloromethane (mixture A). The mixture (A) is stirred at room temperature until a homogeneous solution was obtained. To a 65 ml plastic container are added 0.0817 g (0.3084 mmol) of [(1,5-cyclooctadiene)Pd(CH₃)(Cl)], 0.0809 g (0.3084 mmol) of PPh₃, 0.2733 g (0.3084 mmol) of Na[3,5-(CH₃)₂C₆H₃]₄B and 33 ml of dichloromethane (mixture B). The mixture (B) is shaken at room temperature until a homogeneous solution is obtained. The mixture (B) is then added to mixture (A) under nitrogen and the reaction mixture is heated to reflux under nitrogen with vigorously stirring for 24 hours. The solution iss then precipitated in 586 ml of methanol. Polymer is collected by filtration and dried under reduced pressure.

A layer is made and baked. At an appropriate time in an integration scheme, the baked layer is decomposed and the decomposed layer is volatilized to form a gas layer.

### INVENTIVE EXAMPLE 10

### Preparation of Poly(5-Phenyl-2-Norbornene-co-5-Triethoxysilyl-2-Norbornene-co-lndene)

Poly(5-phenyl-2-norbornene-co-5-Triethoxysilyl-2-norbornene-co-indene) may be prepared according to the following method: April D. Hennis, Jennifer D. Polley, Gregory S. Long, Ayusman Sen, Dmitry Yandulov, John Lipian, Geroge M. Benedikt, and Larry F. Rhodes Organometallics 2001, 20, 2802. To a 500-mL three-neck flask with a magnetic stirrer and nitrogen inlet and outlet are added 25.00 g (0.1468 mol) of 5-phenyl-2-norbornene, 17.06 g (0.1468 mol) of indene, 3.77 g (0.01648 mol) of 5-triethoxysilyl-2-norbornene and 229 ml of dichloromethane (mixture A). The mixture (A) is stirred at room temperature until a homogeneous solution was obtained. To a 65 ml plastic container are added 0.0817g (0.3084 mmol) of [(1,5-cyclooctadiene)Pd(CH₃) (Cl)], 0.0809 g (0.3084 mmol) of PPh₃, 0.2733 g (0.3084 mmol) of Na[3,5-(CH₃)₂C₆H₃]₄B and 33 ml of dichloromethane (mixture B). The mixture (B) is shaken at room temperature until a homogeneous solution is obtained. The mixture (B) is then added to mixture (A) under nitrogen and the reaction mixture is heated to reflux under nitrogen with vigorously stirring for 24 hours. The solution is then precipitated in 458 ml of methanol. Polymer is collected by filtration and dried under reduced pressure.

A layer is made and baked. At an appropriate time in an integration scheme, the baked layer is decomposed and the decomposed layer is volatilized to form a gas layer.

### INVENTIVE EXAMPLE 11

PAN 1 and PAN 2 made by Inventive Example 5 above have the properties in the following Tables 7 and 8 where AN stands for acenaphthylene and PDI stands for polydispersion index.

TABLE 7

| | PAN 1 | PAN 2 |
|---|---|---|
| Monomer | AN | AN |
| Si wt % | 0 | 0 |
| Initiator | DBADC | DBADC |
| Initiator % | 0.1% | 0.5% |
| Solvent | Xylene | Xylene |
| Temperature (C) | 140 | 140 |
| Time (hr) | 6 | 6 |
| Mn | 8,959 | 6,936 |
| Mw | 23,281 | 18,381 |
| PDI | 2.60 | 2.65 |

This composition had two weight percent of an adhesion promoter of hydridopolycarbosilane.

TABLE 8

| PROPERTY | DETAILS | PAN 1 | PAN 2 |
|---|---|---|---|
| Wt loss % | 0-300° C. | 1.265 | 1.795 |
| Ramp 1 | 300° C. for 1 hour | 1.093 | 1.448 |
| | 300-350° C. | 0.771 | 1.108 |
| | 350° C. for 1 hour | 48.390 | 48.220 |
| | 350-500° C. | 21.820 | 20.200 |
| | Total | 73.339 | 72.771 |
| Wt loss % | 0-250° C. | 0.971 | 1.409 |
| Ramp 2 | 250° C. for 10 minutes | 0.211 | 0.321 |
| | 250-425° C. | 66.140 | 64.680 |
| | 425° C. for 1 hour | 17.960 | 15.470 |
| | Total | 85.282 | 81.880 |
| Glass Transition (Tg) (° C.) | DSC | 309 | 304 |

PAN 1 from Table 7 above was applied to a Si-based substrate and baked. The baked film had the properties in the following Table 9:

TABLE 9

| PROPERTY | PAN 1 | PAN 2 |
|---|---|---|
| Thickness (Angstroms) | 5299.4 | 4662 |
| Refractive Index | 1.6805 | 1.6809 |
| (@ 633 nm) | | |
| Film Quality | Good | Good |

The preceding was repeated except that PAN 2 instead of PAN 1 was used.

### INVENTIVE EXAMPLE 2

PAN 1 from Table 7 above was applied to an oxide based substrate. The applied material was baked (100° C., 200° C., 350° C. at one minute each) and then degraded (425° C./one hour). The baked film had the properties in the following Table 10:

TABLE 10

| PROCESSING | PROPERTY | PAN 1 | PAN 2 |
|---|---|---|---|
| Post Bake | Thickness | 5327 | 4659.7 |
| | (Angstroms) | | |
| | Index (@ 633 nm) | 1.6815 | 1.6852 |
| | SiO₂ | — | — |
| Film Quality | Visual | Good | Good |
| Post Degradation | Thickness | 503.17 | 456.02 |
| | Index (@ 633 nm) | 1.6972 | 1.7003 |
| | SiO₂ | — | — |
| | Conductivity | Not detectable | Not detectable |
| | (4 point probe) | | |

The preceding was repeated except that PAN 2 instead of PAN 1 was used.

### INVENTIVE EXAMPLE 13

PAN 1 from Table 7 above was formulated with an adhesion promoter as follows. To a 500-mL flask with a magnetic stirrer were added 50.00g of PAN 1, 3.35 g of hydridopolycarbosilane, and 214.39 g of cyclohexanone. The mixture was stirred at room temperature overnight. The homogeneous solution that obtained was then filtered through 0.45 μm PTFE filter once and 0.10 μm PTFE filter twice. The composition was applied to an silicon based substrate. The applied material was baked (100° C., 200° C., 350° C. at one minute each) and then degraded (425° C./one hour). The baked film had the properties in the following Tables 11 and 12:

TABLE 11

| PROPERTY | DETAILS | PAN 1 |
|---|---|---|
| Wt loss % | 0-250° C. | 0.110% |
| Ramp 1 | 250° C. for 10 | 0.021% |
| | minutes | |
| | 250-300° C. | 0.122% |
| | 300° C. for 1 hour | 1.526% |
| Wt loss % | 0-250° C. | 0.131% |
| Ramp 2 | 250° C. for 10 minutes | 0.024% |
| | 250-425° C. | 71.550% |
| | 425° C. for 1 hour | 4.284% |
| | 425° C. for 1 hour | 0.036% |
| | Total | 75.950% |
| Glass Transition (Tg) (° C.) | DSC | 309 |

TABLE 12

| PROPERTY | PAN 1 |
|---|---|
| Thickness (Angstroms) | 10246 |
| Sigma % | 1.43% |
| Refractive Index (@ 633 nm) | 1.667 |
| Film Quality | Good |
| Modulus (Gpa) | 6.694 |
| Hardness (Gpa) | 0.378 |
| BET | Film did not have any |
| | measurable porosity. |

### INVENTIE EXAMPLE 14

To improve the thermal stability of polyacenaphthylene, a 300° C. cure occurred. To a 500-mL flask with a magnetic stirrer were added 50.00 g of polyacenaphthylene, 3.35 g of hydridopolycarbosilane and 214.39 g of cyclohexanone. The mixture was at room temperature overnight. The homogeneous solution that obtained was then filtered through 0.45 μm PTFE filter once and 0.10 μm PTFE filter twice. The composition was applied to a Si based substrate. The applied material was baked (150° C., 250° C., and 300° C. at one minute each) and then cured (300° C. for one hour). The film had the properties in the following Table 13

TABLE 13

| PROPERTY | DETAILS | | Cured PAN |
|---|---|---|---|
| Wt loss % | 0-250° C. | | 0.053% |
| Ramp | 250° C. | for 10 minutes | 0.010% |
| | 250-300° C. | | 0.032% |
| | 300° C. | for 1 hour | 0.987% |

### INVENTIVE EXAMPLE 15

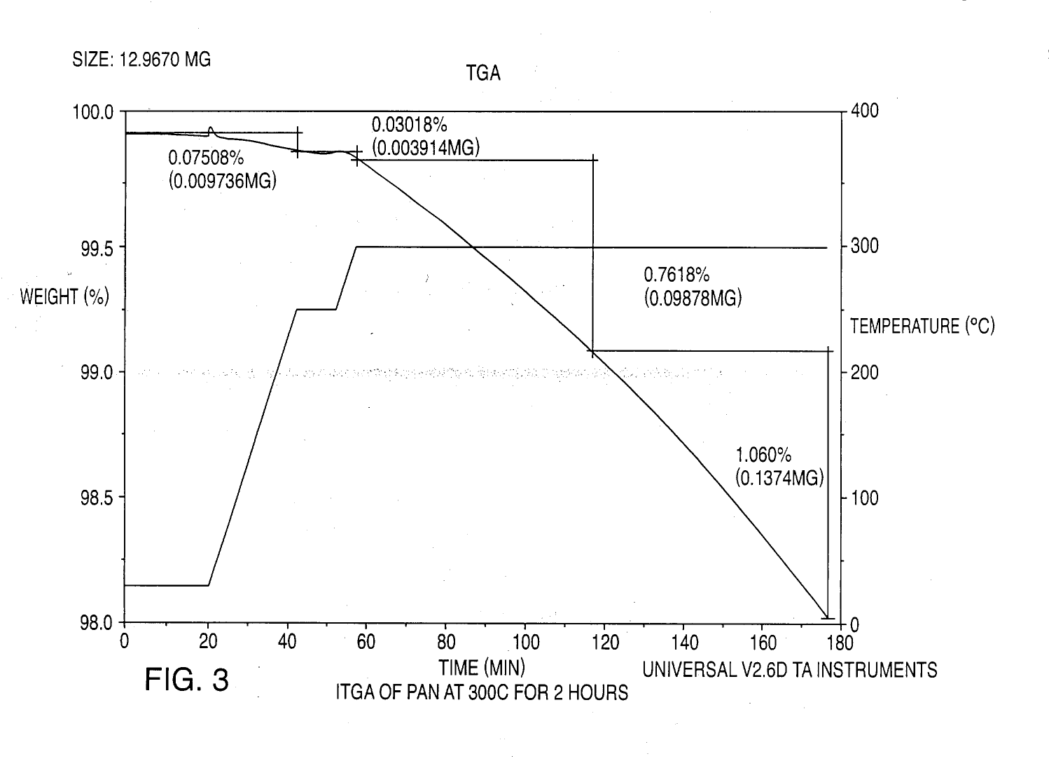

To improve the thermal stability of polyacenaphthylene, the following chemical monomer modification occurred. To a 50-mL flask with a magnetic stirrer were added 2.40 g of polyacenaphthylene of Table 14 below, 0.24 g of hydrolysis oligomer of tetraacetoxysilane and methyltriacetoxysilane and 17.17 g of cyclohexanone. The mixture was stirred at room temperature for 2 hours. The homogeneous solution that obtained was then filtered through 0.45 μm PTFE filter once and 0.10 μm PTFE filter twice. The thermal properties are in Table 15 below and FIG. 3.

TABLE 14

| Monomer | AN |
|---|---|
| Si wt % | 0 |
| Initiator | DBADC |
| Initiator % | 0.20% |
| Solvent | xylene |
| Temperature | 140 |
| (C.) | |
| Time (hr) | 6 |
| Mn | 12161 |
| Mw | 30872 |
| PDI | 2.54 |

TABLE 15

| | | | Modified Table |
|---|---|---|---|
| Properties | | | 14 PAN |
| Wt loss % | 0˜250° C. | | 0.07508% |
| Ramp | 250° C. | (10 min) | 0.03018% |
| | 250˜300° C. | | |
| | 300° C. | (1 hr) | 0.76180% |

### INVENTIVE EXAMPLE 16

To improve the thermal stability of polyacenaphthylene, the following chemical monomer modification occurred. To a 50-mL flask with a magnetic stirrer were added 2.600 g of polyacenaphthylene of Table 14 above, 0.234 g of tetraacetoxysilane, 0.026 g of hydridopolycarbosilane, and 17.06 g of cyclohoxanone. The mixture was stirred at room temperature for 2 hours. The homogeneous solution that obtained was then filtered through 0.45 μm PTFE filter once and 0.10 μm PTFE filter twice.

TABLE 16

| | | | Modified |
|---|---|---|---|
| PROPERTY | DETAILS | | Table 14 PAN |
| Wt loss % | 0-250° C. | | 0.1507% |
| Ramp 1 | 250° C. | for 10 minutes | 0.01373% |
| | 250-300° C. | | 0.03819% |
| | 300° C. | for 1 hour | 0.7978% |
| | 300° C. | for 2^{nd} hour | 0.8911% |

### INVENTIVE EXAMPLE 17

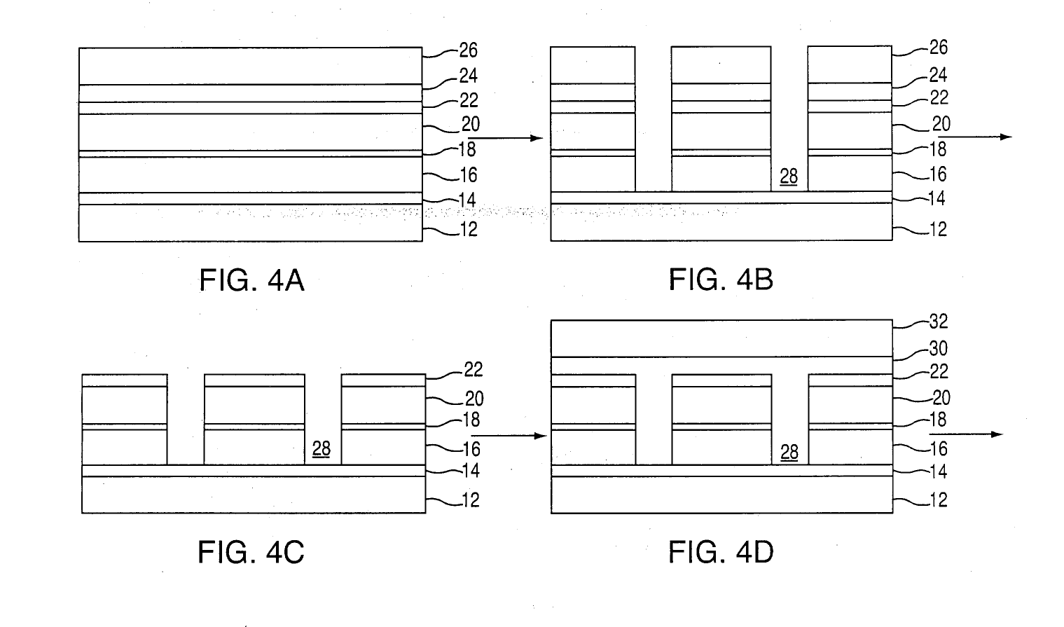

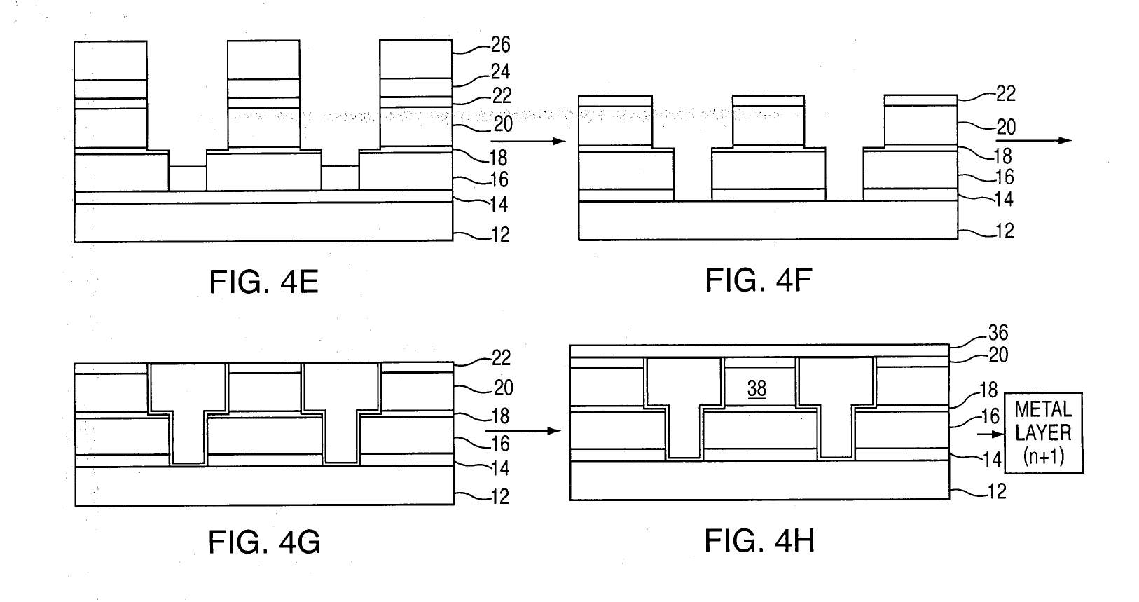

The following integration scheme may be used with the present invention. As shown in FIG. 4, the following steps occur for a copper dual damascene (via-first) integration process flow and illustrate the use of the present invention at the trench level only. Any known deposition or application method including but not limited to spinning and chemical vapor deposition may be used in the following. Any known removal method including but not limited to wet or dry stripping may be used in the following. Any known barrier metal including but not limited to made from Honeywell's tantalum targets or tantalum targets taught by commonly assigned U.S. Pat. Nos. 6,348,139 or 6,331,233 incorporated in their entireties by reference herein may be used in the following. Any known anti-reflective coating including but not limited to Honeywell's DUO™ material or taught by commonly assigned U.S. Pat. Nos. 6,268,457 or 6,365,765 incorporated in their entireties by reference herein may be used in the following. Known processing including but not limited to thermal processing such as baking or cross-linking or reactive gas may be used in the following.

Referring to FIG. 4A, a barrier layer 14 such as SiN and/or SiC was applied to a copper layer 12. A via inter-level layer dielectric 16 was deposited on the barrier layer 14. An etch stop layer 18 was applied to the via inter-level layer dielectric 16. A thermally degradable polymer 20 was applied to the etch stop layer 18 and then processed. Although not illustrated in FIG. 4, an adhesion promoter layer may be deposited on the thermally degradable polymer 20 if needed. A hard mask 22 was deposited on the thermally degradable polymer 20. An anti-reflective coating 24 was applied to the hard mask 22 and then baked. A photoresist 26 was then applied to the anti-reflective coating 24 and then baked. Although not illustrated, via lithography then occurred and photoresist 26 was developed.

Referring to FIG. 4B, via plasma etch 28 of anti-reflective coating 24, hard mask 22, thermally degradable polymer 20, etch stop layer 18, and via level inter-layer dielectric 16 then occurred.

Referring to FIG. 4C, the photoresist 26 was stripped off and the anti-reflective coating 24 was selectively removed. Cleaning then occurred.

Referring to FIG. 4D, gap filling occurred and an anti-reflective material 30 that can be the same as or different than anti-reflective coating 24 was applied. A photoresist 32 that can be the same as or different than photoresist 26 was then applied to the anti-reflective coating 30 and then baked.

Referring to FIG. 4E, trench lithography although not illustrated occurred. The photoresist 32 was then developed. Trench plasma etch 34 of anti-reflective material 30, hard mask 22, and thermally degradable polymer 20 then occurred.

Referring to FIG. 4F, the photoresist 32 was stripped off and the anti-reflective material 30 was selectively removed. Plasma etch 36 of barrier layer 14 to open to copper layer 12 occurred. Cleaning then occurred.

Referring to FIG. 4G, barrier layer 38 and copper seed layer 40 were deposited using PVD (physical vapor deposition), CVD (chemical vapor deposition), and/or ALD (atomic layer deposition). Copper 42 was then plated. Although not illustrated in FIG. 4, CMP or other planarization process occurred to remove copper and barrier on top, and to planarize and stop at the hard mask 22.

Referring to FIG. 4H, the thermally degradable polymer 20 was then substantially degraded and the substantially degraded thermally degradable polymer was then volatilized out of the structure and the gas gap 44 was formed. A barrier layer layer 46 that can be the same or different than barrier layer 14 was deposited to complete the integration of copper layer n.

Although illustrated in FIG. 4, the etch stop layer 18 and its deposition step may be skipped if etch selectivity between the thermally degradable polymer 20 and the inter-layer dielectric 16 can meet the integration requirements. Although not illustrated in FIG. 4, an adhesion promoter layer and/or surface treatment step, such as a reactive ion etching or a non-reactive gas plasma process, may be applied after the deposition of one layer and prior to the deposition of the following layer when needed.

Regarding hard mask 22 in the integration process flow illustrated by FIG. 4, it is permeable to the effluents of the thermally degradable polymer 20 upon degradation, and is mechanically strong enough to withstand the planarization (FIG. 4G) and thermal degradation (FIG. 4H) processes. Hard mask examples include organic materials (including but not limited to Honeywell GX-3™ material, Polyimides^{[1]}, SiLK™), inorganic materials (including but not limited to SiCN, SiON, SiO₂^{[1]}, FSG, SiN^{[1]}, SiOCN, silicon carbide), or inorganic-organic hybrid materials (including but not limited to Honeywell HOSP™ material, Honeywell HOSP BESt™ material, Honeywell Nanoglass™ material from Spin -On; and Coral™, Black Diamond™, Aurora™, Orion™ from CVD) without or with certain porosity to facilitate the outgassing upon the degradation of a thermally degradable polymer. In addition, the inter-layer dielectric may be selected from the above list of materials. ^{[1]}cf. Hollie A. Reed et al, Presentation at “International SEMATECH Ultra Low k Workshop”, Jun. 6-7, 2002.

### INVENTIVE EXAMPLE 18

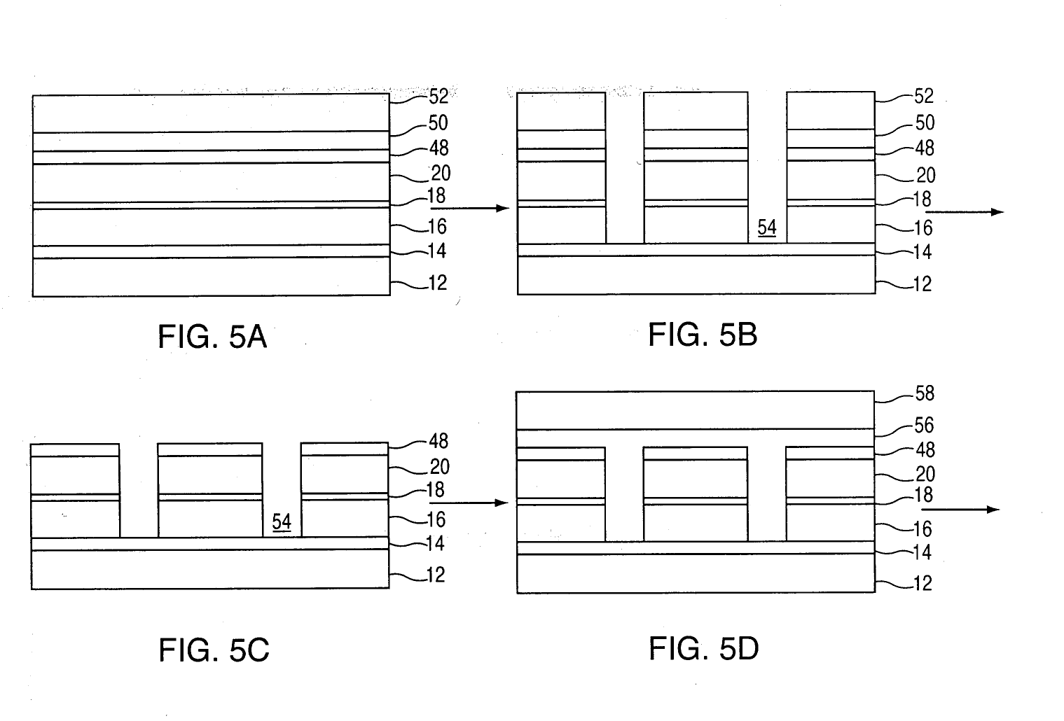

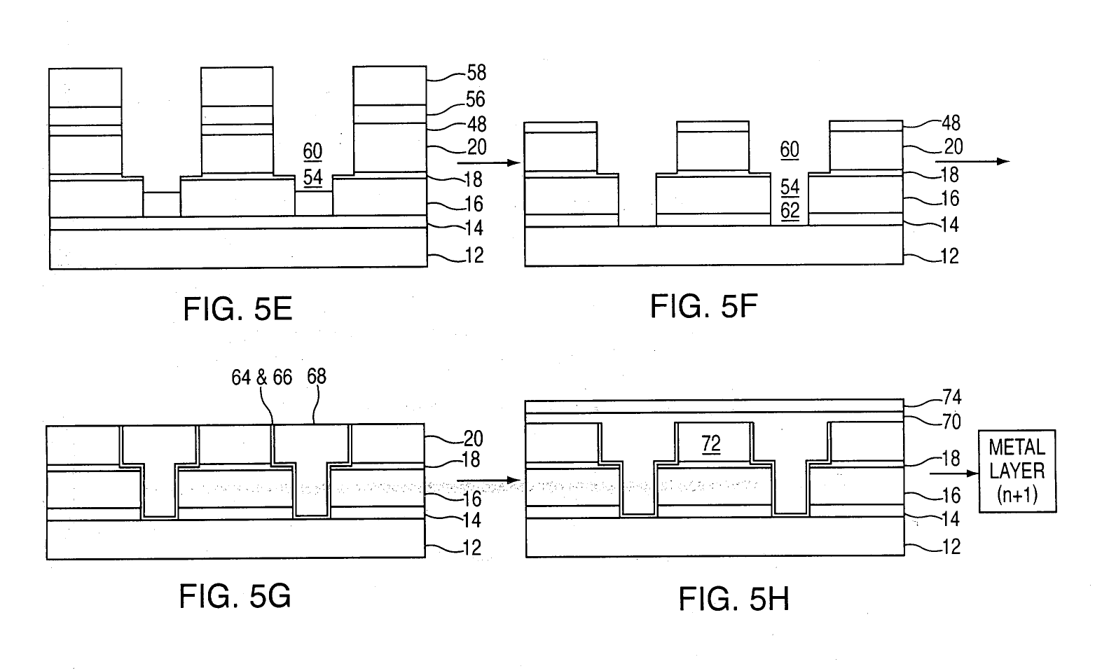

The following describes another integration scheme that may be used with the present invention. As shown in FIG. 5, the following steps occur for a copper dual damascene (via-first) integration process flow and illustrate the use of the present invention at the trench level only. Any known deposition or application method including but not limited to spinning and chemical vapor deposition (CVD) may be used in the following. Any known removal method including but not limited to wet or dry stripping may be used in the following. Any known barrier metal including but not limited to made from Honeywell's tantalum targets or tantalum targets taught by commonly assigned U.S. Pat. Nos. 6,348,139 or 6,331,233 incorporated in their entireties by reference herein may be used in the following. Any known anti-reflective coating including but not limited to Honeywell's DUO™ material or taught by commonly assigned U.S. Pat. Nos. 6,268,457 or 6,365,765 incorporated in their entireties by reference herein may be used in the following.

Referring to FIG. 5A, a barrier layer 14 such as SiN and/or SiC was applied to a copper layer 12. A via level inter-layer dielectric (ILD) 16 was deposited on the barrier layer 14. An etch stop layer 18 was applied to the via level inter-layer dielectric 16. A thermally degradable polymer 20 was applied to the etch stop layer 18 and then thermally processed. The preceding was similar to that of FIG. 4A. Although not illustrated in FIG. 5, an adhesion promoter layer may be deposited on the thermally degradable polymer 20 if needed. Unlike FIG. 4A, cap layer 48 such as SiO₂ was deposited on the thermally degradable polymer 20. An anti-reflective coating (ARC) 50 was applied to the cap layer 48 and then baked. A photoresist 52 was then applied to the anti-reflective coating 50 and then baked. Although not illustrated, via lithography then occurred and photoresist 52 was developed.

Referring to FIG. 5B, via plasma etch 54 of anti-reflective coating 50, cap 48, thermally degradable polymer 20, etch stop layer 18, and via level inter-layer dielectric 16 then occurred.

Referring to FIG. 5C, the photoresist 52 was stripped off and the anti-reflective coating 50 was selectively removed. Cleaning then occurred.

Referring to FIG. 5D, gap filling occurred and an anti-reflective material 56 that can be the same as or different than anti-reflective material 50 was applied. A photoresist 58 that can be the same as or different than photoresist 52 was then applied to the anti-reflective coating 56 and then baked.

Referring to FIG. 5E, trench lithography although not illustrated occurred. The photoresist 58 was then developed. Trench plasma etch 60 of anti-reflective material 56, cap 48, and thermally degradable polymer 20 then occurred.

Referring to FIG. 5F, the photoresist 58 was stripped off and the anti-reflective material 56 was selectively removed. Plasma etch 62 of barrier layer 14 to open to copper layer 12 occurred. Cleaning then occurred.

Referring to FIG. 5G, barrier layer 64 and copper seed layer 66 were deposited using PVD (physical vapor deposition), CVD (chemical vapor deposition), and/or ALD (atomic layer deposition). Copper 68 was then plated. Although not illustrated in FIG. 5, CMP or other planarization process occurred to remove copper and barrier on top as well as cap layer 48, and to stop at the thermally degradable polymer layer 20.

If the thermally degradable polymer can withstand additional processing, the following optional hard mask and cap layer will not be needed. Referring to FIG. 5H, an optional hard mask 70 was deposited on the thermally degradable polymer 20. As an alternative to optional hard mask 70 and not illustrated, an optional cap layer may be deposited on the thermally degradable polymer 20. The thermally degradable polymer 20 was then substantially degraded and volatilized out of the structure, and the gas gap 72 was generated. A barrier layer 74 that can be the same as or different than barrier layer 14 was deposited to complete the integration of copper layer n.

Although illustrated in FIG. 5, the etch stop layer 1 8 and its deposition step can be skipped if etch selectivity between the thermally degradable polymer 20 and the inter-layer dielectric 16 can meet the integration requirements. Although not illustrated in FIG. 4, an adhesion promoter layer and/or surface treatment step, such as a RIE or a non-reactive gas plasma process, may be applied after the deposition of one layer and prior to the deposition of the following layer when needed.

Although illustrated in FIG. 5, the cap layer 48 and its deposition step can be skipped if direct planarization can be performed with the thermally degradable polymer 20. Hard mask 70 in the integration process flow illustrated by FIG. 5 can use the same material 22 in FIG. 4.

### INVENTIVE EXAMPLE 19

In another integration scheme, thermally degradable polymer layers are formed at both the via and trench levels and then substantially degraded and volatilized out of the structure to generate gas layers at both the via and trench levels. These gas layers may be formed from the same or different thermally degradable polymers. A dual damascene process flow is used following Inventive Examples 17 and 18. Instead of depositing a standard via level interlevel dielectric 16 as described in Inventive Examples 17 and 18, a thermally degradable polymer 16 is deposited at the via level. Following the integration process flow of these examples, a second thermally degradable polymer 20 is deposited at the trench level. After further processing as illustrated in Inventive Examples 17 and 18, both thermally degradable polymer layers 16 and 20 are degraded and volatilized out of the structure leaving a gas layer(s) at both the via and trench levels. Etch stop layers may or may not be used based on the etch/process selectivity of the via and trench level inter-level dielectrics 16 and 20.

What is claimed:

1. Gas layer formation material selected from the group consisting of acenaphthylene homopolymers; acenaphthylene copolymers; norbornene and acenaphthylene copolymer; polynorbornene derivatives; blend of polynorbornene and polyacenaphthylene; poly(arylene ether); polyamide; B-staged multifunctional acrylate/methacrylate; crosslinked styrene divinyl benzene polymers; and copolymers of styrene and divinyl benzene with maleimide or bis-maleimides.

2. The gas layer formation material of claim 1 having less than two percent weight loss after holding at 300° C. for one hour.

3. The gas layer formation material of claim 2 wherein said material is selected from the group consisting of acenaphthylene homopolymers and acenaphthylene copolymers.

4. The gas layer formation material of claim 1 additionally comprising an adhesion promoter.

5. The gas layer formation material of claim 1 additionally comprising silane of the following formula 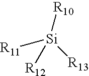
where R₁₀, R₁₁, R₁₂, and R₁₃ is the same or different and selected from the group consisting of hydrogen, alkyl, aryl, alkoxy, aryloxy, acetoxy, chlorine, or combinations thereof, and where at least one of R₁₀, R₁₁, R₁₂, and R₁₃ is alkoxy, aryloxy, acetoxy, or chlorine; organosiloxane; phenysiloxane polymer; methylphenylsiloxane polymer; siloxane polymer; hydrogen silsesquioxane; or methyl silsesquioxane.

6. A spin-on depositable material comprising said gas layer formation material of claim 1.

7. A chemical vapor deposition precursor comprising said gas layer formation material of claim 1.

8. A film comprising said gas layer formation material of claim 1.

9. A substrate having said film of claim 8 thereon.

10. A method of forming a gas layer comprising the step of: using a gas layer formation material selected from the group consisting of acenaphthylene homopolymers; acenaphthylene copolymers; norbornene and acenaphthylene copolymer; polynorbornene derivatives; blend of polynorbornene and polyacenaphthylene; poly(arylene ether); polyamide; B-staged multifunctional acrylate/methacrylate; crosslinked styrene divinyl benzene polymers; and copolymers of styrene and divinyl benzene with maleimide or bis-maleimides.

11. The method of claim 10 wherein said material has less than two percent weight loss after holding at 300° C. for one hour.

12. The method of claim 10 wherein said material is selected from the group consisting of acenaphthylene homopolymers and acenaphthylene copolymers.

13. The method of claim 10 wherein said material additionally comprises adhesion promoter.

14. The method of claim 10 wherein said material additionally comprises silane of the following formula 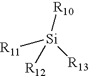
where R₁₀, R₁₁, R₁₂, and R₁₃ is the same or different and selected from the group consisting of hydrogen, alkyl, aryl, alkoxy, aryloxy, acetoxy, chlorine, or combinations thereof, and where at least one of R₁₀, R₁₁, R₁₂, and R₁₃ is alkoxy, aryloxy, acetoxy, or chlorine; organosiloxane; phenysiloxane polymer; methylphenylsiloxane polymer; siloxane polymer; hydrogen silsesquioxane; or methyl silsesquioxane.

15. A process comprising the steps of:
(a) in an inter-level dielectric layer, incorporating a polymer having: (i) a glass transition temperature of greater than about 200° C., (ii) less than two percent weight loss after holding at 300° C. for one hour, and (iii) a decomposition temperature of greater than about 350° C.;
(b) heating said polymer to a temperature of greater than about 350° C.; and
(c) removing the heated polymer.

16. The process of claim 15 wherein said polymer is selected from the group consisting of acenaphthylene homopolymers and acenaphthylene copolymers.

17. The process of claim 15 wherein said polymer additionally comprises adhesion promoter.

18. The process of claim 15 wherein said polymer additionally comprises silane of the following formula 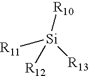
where R₁₀, R₁₁, R₁₂, and R₁₃ is the same or different and selected from the group consisting of hydrogen, alkyl, aryl, alkoxy, aryloxy, acetoxy, chlorine, or combinations thereof, and where at least one of R₁₀, R₁₁, R₁₂, and R₁₃ is alkoxy, aryloxy, acetoxy, or chlorine; organosiloxane; phenysiloxane polymer; methylphenylsiloxane polymer; siloxane polymer; hydrogen silsesquioxane; or methyl silsesquioxane.

19. The process of claim 15 additionally comprising prior to said step (b), treating said polymeric layer by exposure to electron beam radiation, ion beam radiation, microwave radiation, ultraviolet radiation, infrared radiation, or x-ray.

20. A microchip comprising a gas layer wherein the gas layer is formed by:
(a) forming a layer of polymer having: (i) a glass transition temperature of greater than about 200° C., (ii) less than two percent weight loss after holding at 300° C. for one hour, and (iii) a decomposition temperature of greater than about 350° C.;
(b) decomposing the polymeric layer; and
(c ) volatilizing the decomposed polymeric layer wherein the gas layer forms.

21. The microchip of claim 20 wherein said polymer layer is formed on a substrate.

22. A microelectronic device comprising:
(a) substrate;
(b) a layer of thermally degradable polymer having a glass transition temperature of at least 200° C. and is capable of being degraded and volatilized;
(c) porous capping layer adjacent to said polymeric layer; and
(d) metal barrier layer adjacent to the ends of said polymeric layer.

23. The microelectronic device of claim 22 wherein said thermally degradable polymer is selected from the group consisting of acenaphthylene homopolymers; acenaphthylene copolymers; norbornene and acenaphthylene copolymer; polynorbornene derivatives; blend of polynorbornene and polyacenaphthylene; poly(arylene ether); polyamide; B-staged multifunctional acrylate/methacrylate; crosslinked styrene divinyl benzene polymers; and copolymers of styrene and divinyl benzene with maleimide or bis-maleimides.

24. A process for forming a microelectronic device comprising the steps of:
(a) applying thermally degradable polymer having a glass transition temperature of at least 200° C. on a substrate;
(b) applying a porous capping layer on said thermally degradable polymer layer;
(c) patterning said thermally degradable polymer and porous capping layers;
(d) applying metal barrier layer to said patterned layer;
(e) thermally degrading said polymer; and
(f) volatilizing said degraded polymer to form a gas layer.

25. The process of claim 24 wherein said thermally degradable polymer is selected from the group consisting of acenaphthylene homopolymers; acenaphthylene copolymers; norbornene and acenaphthylene copolymer; polynorbornene derivatives; blend of polynorbornene and polyacenaphthylene; poly(arylene ether); polyamide; B-staged multifunctional acrylate/methacrylate; crosslinked styrene divinyl benzene polymers; and copolymers of styrene and divinyl benzene with maleimide or bis-maleimides.

26. The process of claim 24 additionally comprising prior to said step (e), treating said thermally degradable polymer by exposure to electron beam radiation, ion beam radiation, microwave radiation, ultraviolet radiation, infrared radiation, or x-ray.
